(19) United States
(12) Patent Application Publication
(10) Pub. No.: US 2025/0080253 A1
(43) Pub. Date: Mar. 6, 2025

(54) FREQUENCY DEPENDENT RESIDUAL SIDEBAND DISTORTION CANCELLATION

(71) Applicant: QUALCOMM Incorporated, San Diego, CA (US)

(72) Inventors: Aviv REGEV, Tel Aviv (IL); Yaniv EISTEIN, Tel Aviv (IL); Ronen SHAKED, Kfar Saba (IL); Amit MOSES, Tel Aviv (IL)

(21) Appl. No.: 18/240,993

(22) Filed: Aug. 31, 2023

(51) Int. Cl. H04B 17/336; H04L 1/00; H04L 5/00

(52) U.S. Cl. CPC H04B 17/336; H04L 1/0003; H04L 5/0098

(57) ABSTRACT

Various aspects are described herein for frequency dependent residual sideband (FDRSB) cancellation. A network node may measure an FDRSB distortion and may calculate a thermal noise based at least in part on the FDRSB distortion and a received signal-to-noise ratio (SNR). The network node may identify, based at least in part on the thermal noise, the FDRSB, and a modulation and coding scheme (MCS), whether to enable or disable FDRSB cancellation at a user equipment (UE). The network node may transmit an FDRSB cancellation message that indicates for the UE to enable FDRSB cancellation or that indicates for the UE to disable FDRSB cancellation, and the UE may selectively perform FDRSB cancellation based at least in part on the FDRSB cancellation message. This may reduce UE processing resources, UE energy consumption, and latency at a demodulator of the UE.

### FIELD OF THE DISCLOSURE

Aspects of the present disclosure generally relate to wireless communication and to techniques and apparatuses for frequency dependent residual sideband distortion cancellation.

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, or the like). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless network may include one or more network nodes that support communication for wireless communication devices, such as a user equipment (UE) or multiple UEs. A UE may communicate with a network node via downlink communications and uplink communications. “Downlink” (or “DL”) refers to a communication link from the network node to the UE, and “uplink” (or “UL”) refers to a communication link from the UE to the network node. Some wireless networks may support device-to-device communication, such as via a local link (e.g., a sidelink (SL), a wireless local area network (WLAN) link, and/or a wireless personal area network (WPAN) link, among other examples).

The above multiple access technologies have been adopted in various telecommunication standards to provide a common protocol that enables different UEs to communicate on a municipal, national, regional, and/or global level. 5G, which may be referred to as New Radio (NR), is a set of enhancements to the LTE mobile standard promulgated by the 3GPP. 5G is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM and/or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in 4G, 5G, and other radio access technologies remain useful.

### SUMMARY

Frequency dependent residual sideband (FDRSB) impairment may be caused by a signal transmission mismatch (such as a quadrature signal (IQ signal) mismatch), and may result in radio frequency impairments that limit data transmission rates. FDRSB impairment may become more significant as carrier frequency increases. When transmissions are performed using massive multiple-input multiple-output (MIMO) communications, FDRSB may increase in accordance with the number of transmission antennas. In some cases, FDRSB may be calibrated at a network node to enable transmissions of legacy quadrature amplitude modulation (QAM) signals (up to 250 QAM). In order to achieve this transmission rate, the FDRSB impairment may be calibrated to be below 30 decibels relative to the carrier (dBc). However, for superQAM modulation transmission rates (up to 16 thousand (16K) QAM), the FDRSB power may need to be lower (e.g., significantly lower) than 30 dBc. Thus, FDRSB mitigation may be needed.

Some UEs may be configured to estimate the FDRSB and to cancel the FDRSB. In this case, FDRSB cancellation may be performed regardless of the FDRSB power, for example, since the UE may not be able to identify whether the channel noise is caused by thermal noise (or mostly thermal noise) or by FDRSB noise (or mostly FDRSB noise). The FDRSB cancellation process at the UE may include estimating the experienced FDRSB, and removing the FDRSB based at least in part on the estimated FDRSB. This process may incur high complexity, may increase digital power consumption, and may increase a latency at the UE demodulator. In some cases, such as when the channel noise results largely from thermal noise and/or when an estimated signal-to-noise ratio (SNR) is sufficient for demodulating a current modulation and coding scheme (MCS), the high-complexity FDRSB cancellation process may not be necessary, thereby resulting in wasted UE processing and energy resources, as well as increased latency.

Various aspects are described herein for FDRSB cancellation. A network node may measure an FDRSB distortion. The network node may calculate a thermal noise based at least in part on the FDRSB distortion and an SNR. In some examples, calculating the thermal noise based at least in part on the FDRSB may include obtaining a quotient by dividing an SNR received from a UE from one, and subtracting the measured FDRSB distortion from the quotient. The network node may identify, based at least in part on the thermal noise, the FDRSB, and the MCS, whether to enable or disable FDRSB cancellation at the UE. The network node may generate an FDRSB cancellation message that indicates to enable the FDRSB cancellation at the UE or that indicates to disable the FDRSB cancellation at the UE. For example, the network node may generate an FDRSB cancellation message that indicates to enable the FDRSB cancellation at the UE in accordance with identifying to enable the FDRSB cancellation at the UE, or may generate an FDRSB cancellation message that indicates to disable the FDRSB cancellation at the UE in accordance with identifying the disable the FDRSB cancellation at the UE. The network node may transmit, and the UE may receive, the FDRSB cancellation message, and the UE may selectively perform FDRSB cancellation based at least in part on the FDRSB cancellation message. For example, the UE may perform FDRSB cancellation in accordance with the FDRSB cancellation message indicating to enable the FDRSB cancellation, or may refrain from performing FDRSB cancellation in accordance with the FDRSB cancellation message indicating to disable the FDRSB cancellation. By determining, at the network node, whether FDRSB cancellation is to be performed, and by transmitting the FDRSB cancellation message to the UE indicating whether the FDRSB is to be performed. UE processing resources, UE energy consumption, and latency at a UE demodulator may be reduced. For example, the UE may refrain from performing FDRSB cancellation in accordance with the network node identifying that a channel noise results largely from thermal noise, and/or in accordance with the network node identifying that an estimated SNR is sufficient for demodulating a current MCS. These example advantages, among others, are described in more detail herein.

In some implementations, a method of wireless communication performed by a network node includes measuring a frequency dependent residual sideband distortion; calculating a thermal noise based at least in part on the frequency dependent residual sideband distortion and a signal-to-noise ratio; identifying, based at least in part on the thermal noise, the frequency dependent residual sideband distortion, and a modulation and coding scheme, whether to enable or disable frequency dependent residual sideband cancellation at a device; and transmitting an indication for the device to enable the frequency dependent residual sideband cancellation or an indication for the device to disable the frequency dependent residual sideband cancellation.

In some implementations, a method of wireless communication performed by a UE includes receiving an indication to enable frequency dependent residual sideband cancellation or an indication to disable frequency dependent residual sideband cancellation; and selectively performing frequency dependent residual sideband cancellation in accordance with the indication to enable the frequency dependent residual sideband cancellation or the indication to disable frequency dependent residual sideband cancellation.

In some implementations, an apparatus for wireless communication at a network node includes one or more memories; and one or more processors coupled to the one or more memories, the one or more processors individually or collectively configured to cause the network node to: measure a frequency dependent residual sideband distortion; calculate a thermal noise based at least in part on the frequency dependent residual sideband distortion and a signal-to-noise ratio; identify, based at least in part on the thermal noise, the frequency dependent residual sideband distortion, and a modulation and coding scheme, whether to enable or disable frequency dependent residual sideband cancellation at a device; and transmit an indication for the device to enable the frequency dependent residual sideband cancellation or an indication for the device to disable the frequency dependent residual sideband cancellation.

In some implementations, an apparatus for wireless communication at a UE includes one or more memories; and one or more processors coupled to the one or more memories, the one or more processors individually or collectively configured to cause the UE to: receive an indication to enable frequency dependent residual sideband cancellation or an indication to disable frequency dependent residual sideband cancellation; and selectively perform frequency dependent residual sideband cancellation in accordance with the indication to enable the frequency dependent residual sideband cancellation or the indication to disable frequency dependent residual sideband cancellation.

In some implementations, a non-transitory computer-readable medium storing a set of instructions for wireless communication includes one or more instructions that, when executed by one or more processors of a network node, cause the network node to: measure a frequency dependent residual sideband distortion; calculate a thermal noise based at least in part on the frequency dependent residual sideband distortion and a signal-to-noise ratio; identify, based at least in part on the thermal noise, the frequency dependent residual sideband distortion, and a modulation and coding scheme, whether to enable or disable frequency dependent residual sideband cancellation at a device; and transmit an indication for the device to enable the frequency dependent residual sideband cancellation or an indication for the device to disable the frequency dependent residual sideband cancellation.

In some implementations, anon-transitory computer-readable medium storing a set of instructions for wireless communication includes one or more instructions that, when executed by one or more processors of a UE, cause the UE to: receive an indication to enable frequency dependent residual sideband cancellation or an indication to disable frequency dependent residual sideband cancellation; and selectively perform frequency dependent residual sideband cancellation in accordance with the indication to enable the frequency dependent residual sideband cancellation or the indication to disable frequency dependent residual sideband cancellation.

In some implementations, an apparatus for wireless communication includes means for measuring a frequency dependent residual sideband distortion; means for calculating a thermal noise based at least in part on the frequency dependent residual sideband distortion and a signal-to-noise ratio; means for identifying, based at least in part on the thermal noise, the frequency dependent residual sideband distortion, and a modulation and coding scheme, whether to enable or disable frequency dependent residual sideband cancellation at a device; and means for transmitting an indication for the device to enable the frequency dependent residual sideband cancellation or an indication for the device to disable the frequency dependent residual sideband cancellation.

In some implementations, an apparatus for wireless communication includes means for receiving an indication to enable frequency dependent residual sideband cancellation or an indication to disable frequency dependent residual sideband cancellation; and means for selectively performing frequency dependent residual sideband cancellation in accordance with the indication to enable the frequency dependent residual sideband cancellation or the indication to disable frequency dependent residual sideband cancellation.

Aspects generally include a method, apparatus, system, computer program product, non-transitory computer-readable medium, user equipment, base station, wireless communication device, network entity, network node, and/or processing system as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

FIG. 1 is a diagram illustrating an example of a wireless network.

FIG. 2 is a diagram illustrating an example of a network node in communication with a user equipment (UE) in a wireless network.

FIG. 3 is a diagram illustrating an example disaggregated base station architecture.

FIG. 4 is a diagram illustrating examples of frequency dependent residual sideband impairment.

FIG. 5 is a diagram illustrating an example of frequency dependent residual sideband cancellation.

FIG. 6 is a diagram illustrating an example of a frequency dependent residual sideband measurement.

FIG. 7 is a flowchart of an example method of wireless communication.

FIG. 8 is a flowchart of an example method of wireless communication.

FIG. 9 is a diagram of an example apparatus for wireless communication.

FIG. 10 is a diagram illustrating an example of a hardware implementation for an apparatus employing a processing system.

FIG. 11 is a diagram of an example apparatus for wireless communication.

FIG. 12 is a diagram illustrating an example of a hardware implementation for an apparatus employing a processing system.

### DETAILED DESCRIPTION

The detailed description set forth below in connection with the appended drawings is intended as a description of various configurations and is not intended to represent the configurations in which the concepts described herein may be practiced. The detailed description includes specific details for the purposes of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of telecommunication systems will now be presented with reference to various apparatus and methods. These apparatus and methods will be described in the following detailed description and illustrated in the accompanying drawings by various blocks, modules, components, circuits, steps, processes, algorithms, or the like (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, or the like, whether referred to as software, firmware, middleware, microcode, hardware description language, or otherwise.

Accordingly, in one or more example embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can include a random-access memory (RAM), a read-only memory (ROM), an electrically erasable programmable ROM (EEPROM), compact disk ROM (CD-ROM) or other optical disk storage, magnetic disk storage or other magnetic storage devices, combinations of the aforementioned types of computer-readable media, or any other medium that can be used to store computer executable code in the form of instructions or data structures that can be accessed by a computer.

While aspects may be described herein using terminology commonly associated with a 5G or New Radio (NR) radio access technology (RAT), aspects of the present disclosure can be applied to other RATs, such as a 3G RAT, a 4G RAT, and/or a RAT subsequent to 5G (e.g., 6G).

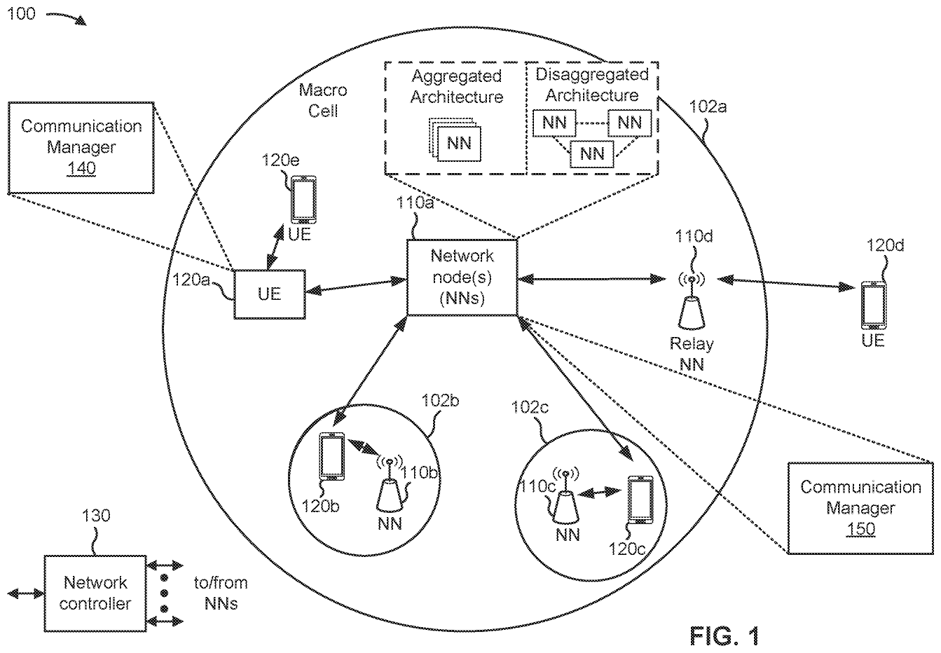

FIG. 1 is a diagram illustrating an example of a wireless network 100. The wireless network 100 may be or may include elements of a 5G (for example, NR) network or a 4G (for example, Long Term Evolution (LTE)) network, among other examples. The wireless network 100 may include one or more network nodes 110 (shown as a network node 110a, a network node 110b, a network node 110c, and a network node 110d), a user equipment (UE) 120 or multiple UEs 120 (shown as a UE 120a, a UE 120b, a UE 120c, a UE 120d, and a UE 120c), or other entities. A network node 110 is an example of a network node that communicates with UEs 120. As shown, a network node 110 may include one or more network nodes. For example, a network node 110 may be an aggregated network node, meaning that the aggregated network node is configured to utilize a radio protocol stack that is physically or logically integrated within a single RAN node (for example, within a single device or unit). As another example, a network node 110 may be a disaggregated network node (sometimes referred to as a disaggregated base station), meaning that the network node 110 is configured to utilize a protocol stack that is physically or logically distributed among two or more nodes (such as one or more central units (CUs), one or more distributed units (DUs), or one or more radio units (RUs)).

In some examples, a network node 110 is or includes a network node that communicates with UEs 120 via a radio access link, such as an RU. In some examples, a network node 110 is or includes a network node that communicates with other network nodes 110 via a fronthaul link or a midhaul link, such as a DU. In some examples, a network node 110 is or includes a network node that communicates with other network nodes 110 via a midhaul link or a core network via a backhaul link, such as a CU. In some examples, a network node 110 (such as an aggregated network node 110 or a disaggregated network node 110) may include multiple network nodes, such as one or more RUs, one or more CUs, and/or one or more DUs. A network node 110 may include, for example, an NR base station, an LTE base station, a Node B, an eNB (for example, in 4G), a gNB (for example, in 5G), an access point, or a transmission reception point (TRP), a DU, an RU, a CU, a mobility element of a network, a core network node, a network element, a network equipment, a RAN node, or a combination thereof. In some examples, the network nodes 110 may be interconnected to one another or to one or more other network nodes 110 in the wireless network 100 through various types of fronthaul, midhaul, and/or backhaul interfaces, such as a direct physical connection, an air interface, or a virtual network, using any suitable transport network.

In some examples, a network node 110 may provide communication coverage for a particular geographic area. In the Third Generation Partnership Project (3GPP), the term “cell” can refer to a coverage area of a network node 110 or a network node subsystem serving this coverage area, depending on the context in which the term is used. A network node 110 may provide communication coverage for a macro cell, a pico cell, a femto cell, or another type of cell. A macro cell may cover a relatively large geographic area (for example, several kilometers in radius) and may allow unrestricted access by UEs 120 with service subscriptions. A pico cell may cover a relatively small geographic area and may allow unrestricted access by UEs 120 with service subscription. A femto cell may cover a relatively small geographic area (for example, a home) and may allow restricted access by UEs 120 having association with the femto cell (for example, UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node. In the example shown in FIG. 1, the network node 110a may be a macro network node for a macro cell 102a, the network node 110b may be a pico network node for a pico cell 102b, and the network node 110c may be a femto network node for a femto cell 102c. A network node may support one or multiple (for example, three) cells. In some examples, a cell may not necessarily be stationary, and the geographic area of the cell may move according to the location of a network node 110 that is mobile (for example, a mobile network node).

In some aspects, the terms “base station” or “network node” may refer to an aggregated base station, a disaggregated base station, an integrated access and backhaul (IAB) node, a relay node, or one or more components thereof. For example, in some aspects, “base station” or “network node” may refer to a CU, a DU, an RU, a Near-Real Time (Near-RI) RAN Intelligent Controller (RIC), or a Non-Real Time (Non-RT) RIC, or a combination thereof. In some aspects, the terms “base station” or “network node” may refer to one device configured to perform one or more functions, such as those described herein in connection with the network node 110. In some aspects, the terms “base station” or “network node” may refer to a plurality of devices configured to perform the one or more functions. For example, in some distributed systems, each of a quantity of different devices (which may be located in the same geographic location or in different geographic locations) may be configured to perform at least a portion of a function, or to duplicate performance of at least a portion of the function, and the terms “base station” or “network node” may refer to any one or more of those different devices. In some aspects, the terms “base station” or “network node” may refer to one or more virtual base stations or one or more virtual base station functions. For example, in some aspects, two or more base station functions may be instantiated on a single device. In some aspects, the terms “base station” or “network node” may refer to one of the base station functions and not another. In this way, a single device may include more than one base station.

The wireless network 100 may include one or more relay stations. A relay station is a network node that can receive a transmission of data from an upstream node (for example, a network node 110 or a UE 120) and send a transmission of the data to a downstream node (for example, a UE 120 or a network node 110). A relay station may be a UE 120 that can relay transmissions for other UEs 120. In the example shown in FIG. 1, the network node 110d (for example, a relay network node) may communicate with the network node 110a (for example, a macro network node) and the UE 120d in order to facilitate communication between the network node 110a and the UE 120d. A network node 110 that relays communications may be referred to as a relay station, a relay base station, a relay network node, a relay node, or a relay, among other examples.

The wireless network 100 may be a heterogeneous network that includes network nodes 110 of different types, such as macro network nodes, pico network nodes, femto network nodes, or relay network nodes. These different types of network nodes 110 may have different transmit power levels, different coverage areas, or different impacts on interference in the wireless network 100. For example, macro network nodes may have a high transmit power level (for example, 5 to 40 watts) whereas pico network nodes, femto network nodes, and relay network nodes may have lower transmit power levels (for example, 0.1 to 2 watts).

A network controller 130 may couple to or communicate with a set of network nodes 110 and may provide coordination and control for these network nodes 110. The network controller 130 may communicate with the network nodes 110 via a backhaul communication link or a midhaul communication link. The network nodes 110 may communicate with one another directly or indirectly via a wireless or wireline backhaul communication link. In some aspects, the network controller 130 may be a CU or a core network device, or may include a CU or a core network device.

The UEs 120 may be dispersed throughout the wireless network 100, and each UE 120 may be stationary or mobile. A UE 120 may include, for example, an access terminal, a terminal, a mobile station, or a subscriber unit. A UE 120 may be a cellular phone (for example, a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (for example, a smart watch, smart clothing, smart glasses, a smart wristband, smart jewelry (for example, a smart ring or a smart bracelet)), an entertainment device (for example, a music device, a video device, or a satellite radio), a vehicular component or sensor, a smart meter/sensor, industrial manufacturing equipment, a global positioning system device, a UE function of a network node, or any other suitable device that is configured to communicate via a wireless or wired medium.

Some UEs 120 may be considered machine-type communication (MTC) or evolved or enhanced machine-type communication (eMTC) UEs. An MTC UE or an eMTC UE may include, for example, a robot, an unmanned aerial vehicle, a remote device, a sensor, a meter, a monitor, or a location tag, that may communicate with a network node, another device (for example, a remote device), or some other entity. Some UEs 120 may be considered Internet-of-Things (IoT) devices, or may be implemented as NB-IoT (narrowband IoT) devices. Some UEs 120 may be considered a Customer Premises Equipment. A UE 120 may be included inside a housing that houses components of the UE 120, such as processor components or memory components. In some examples, the processor components and the memory components may be coupled together. For example, the processor components (for example, one or more processors) and the memory components (for example, a memory) may be operatively coupled, communicatively coupled, electronically coupled, or electrically coupled.

In general, any number of wireless networks 100 may be deployed in a given geographic area. Each wireless network 100 may support a particular RAT and may operate on one or more frequencies. A RAT may be referred to as a radio technology or an air interface. A frequency may be referred to as a carrier or a frequency channel. Each frequency may support a single RAT in a given geographic area in order to avoid interference between wireless networks of different RATs. In some cases, NR or 5G RAT networks may be deployed.

In some examples, two or more UEs 120 (for example, shown as UE 120a and UE 120e) may communicate directly using one or more sidelink channels (for example, without using a network node 110 as an intermediary to communicate with one another). For example, the UEs 120 may communicate using peer-to-peer (P2P) communications, device-to-device (D2D) communications, a vehicle-to-everything (V2X) protocol (for example, which may include a vehicle-to-vehicle (V2V) protocol, a vehicle-to-infrastructure (V2I) protocol, or a vehicle-to-pedestrian (V2P) protocol), or a mesh network. In such examples, a UE 120 may perform scheduling operations, resource selection operations, or other operations described elsewhere herein as being performed by the network node 110.

Devices of the wireless network 100 may communicate using the electromagnetic spectrum, which may be subdivided by frequency or wavelength into various classes, bands, or channels. For example, devices of the wireless network 100 may communicate using one or more operating bands. In 5G NR, two initial operating bands have been identified as frequency range designations FR1 (410 MHz-7.125 GHz) and FR2 (24.25 GHz-52.6 GHz). Although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHz-24.25 GHz). Frequency bands falling within FR3 may inherit FR1 characteristics or FR2 characteristics, and thus may effectively extend features of FR1 or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHz), and FR5 (114.25 GHz-300 GHz). Each of these higher frequency bands falls within the EHF band.

With these examples in mind, unless specifically stated otherwise, the term “sub-6 GHz,” if used herein, may broadly represent frequencies that may be less than 6 GHz, may be within FR1, or may include mid-band frequencies. Further, unless specifically stated otherwise, the term “millimeter wave,” if used herein, may broadly represent frequencies that may include mid-band frequencies, may be within FR2, FR4, FR4-a or FR4-1, or FR5, or may be within the EHF band. It is contemplated that the frequencies included in these operating bands (for example, FR1, FR2, FR3, FR4, FR4-a, FR4-1, or FR5) may be modified, and techniques described herein are applicable to those modified frequency ranges.

In some aspects, the network node 110 may include a communication manager 150. As described in more detail elsewhere herein, the communication manager 150 may measure a frequency dependent residual sideband distortion; calculate a thermal noise based at least in part on the frequency dependent residual sideband distortion and a signal-to-noise ratio; identify, based at least in part on the thermal noise, the frequency dependent residual sideband distortion, and a modulation and coding scheme, whether to enable or disable frequency dependent residual sideband cancellation at a device; and transmit an indication for the device to enable the frequency dependent residual sideband cancellation or an indication for the device to disable the frequency dependent residual sideband cancellation. Additionally, or alternatively, the communication manager 150 may perform one or more other operations described herein.

In some aspects, the UE 120 may include a communication manager 140. As described in more detail elsewhere herein, the communication manager 140 may receive an indication to enable frequency dependent residual sideband cancellation or an indication to disable frequency dependent residual sideband cancellation; and selectively perform frequency dependent residual sideband cancellation in accordance with the indication to enable the frequency dependent residual sideband cancellation or the indication to disable frequency dependent residual sideband cancellation. Additionally, or alternatively, the communication manager 140 may perform one or more other operations described herein.

As indicated above, FIG. 1 is provided as an example. Other examples may differ from what is described with regard to FIG. 1.

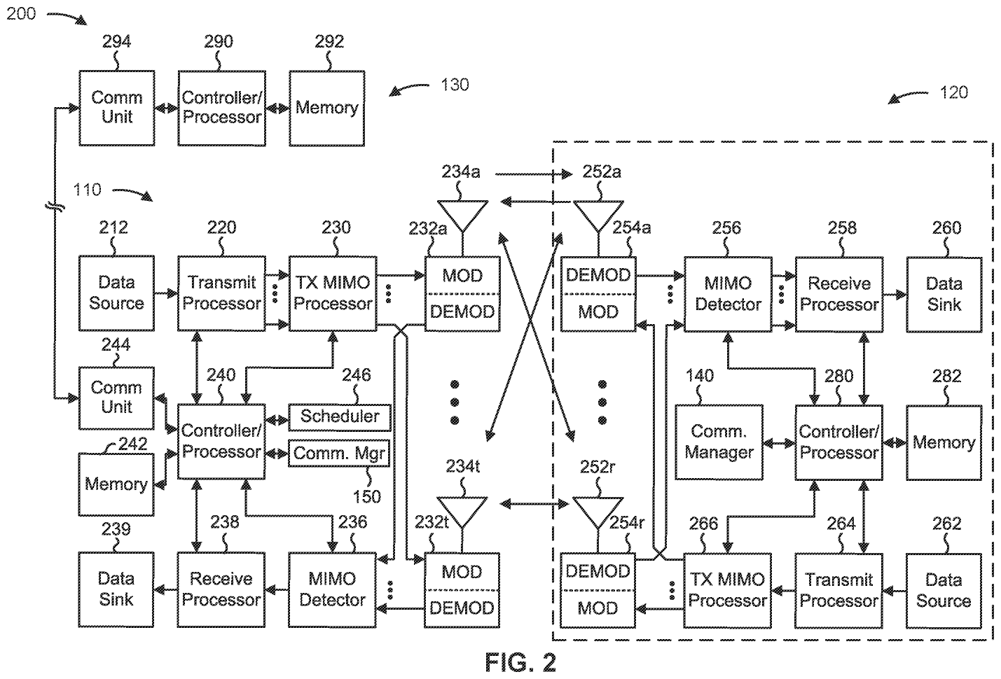

FIG. 2 is a diagram illustrating an example 200 of a network node 110 in communication with a UE 120 in a wireless network 100. The network node 110 may be equipped with a set of antennas 234a through 234t, such as T antennas (T≥1). The UE 120 may be equipped with a set of antennas 252a through 252r, such as R antennas (R≥1). The network node 110 of example 200 includes one or more radio frequency components, such as antennas 234 and a modem 232. In some examples, a network node 110 may include an interface, a communication component, or another component that facilitates communication with the UE 120 or another network node. Some network nodes 110 may not include radio frequency components that facilitate direct communication with the UE 120, such as one or more CUs, or one or more DUs.

At the network node 110, a transmit processor 220 may receive data, from a data source 212, intended for the UE 120 (or a set of UEs 120). The transmit processor 220 may select one or more modulation and coding schemes (MCSs) for the UE 120 using one or more channel quality indicators (CQIs) received from that UE 120. The network node 110 may process (for example, encode and modulate) the data for the UE 120 using the MCS(s) selected for the UE 120 and may provide data symbols for the UE 120. The transmit processor 220 may process system information (for example, for semi-static resource partitioning information (SRPI)) and control information (for example, CQI requests, grants, or upper layer signaling) and provide overhead symbols and control symbols. The transmit processor 220 may generate reference symbols for reference signals (for example, a cell-specific reference signal (CRS) or a demodulation reference signal (DMRS)) and synchronization signals (for example, a primary synchronization signal (PSS) or a secondary synchronization signal (SSS)). A transmit (TX) multiple-input multiple-output (MIMO) processor 230 may perform spatial processing (for example, precoding) on the data symbols, the control symbols, the overhead symbols, or the reference symbols, if applicable, and may provide a set of output symbol streams (for example, T output symbol streams) to a corresponding set of modems 232 (for example, T modems), shown as modems 232a through 232t. For example, each output symbol stream may be provided to a modulator component (shown as MOD) of a modem 232. Each modem 232 may use a respective modulator component to process a respective output symbol stream (for example, for OFDM) to obtain an output sample stream. Each modem 232 may further use a respective modulator component to process (for example, convert to analog, amplify, filter, or upconvert) the output sample stream to obtain a downlink signal. The modems 232a through 232t may transmit a set of downlink signals (for example, T downlink signals) via a corresponding set of antennas 234 (for example, T antennas), shown as antennas 234a through 234t.

At the UE 120, a set of antennas 252 (shown as antennas 252a through 252r) may receive the downlink signals from the network node 110 or other network nodes 110 and may provide a set of received signals (for example, R received signals) to a set of modems 254 (for example, R modems), shown as modems 254a through 254r. For example, each received signal may be provided to a demodulator component (shown as DEMOD) of a modem 254. Each modem 254 may use a respective demodulator component to condition (for example, filter, amplify, downconvert, or digitize) a received signal to obtain input samples. Each modem 254 may use a demodulator component to further process the input samples (for example, for OFDM) to obtain received symbols. A MIMO detector 256 may obtain received symbols from the modems 254, may perform MIMO detection on the received symbols if applicable, and may provide detected symbols. A receive processor 258 may process (for example, demodulate and decode) the detected symbols, may provide decoded data for the UE 120 to a data sink 260, and may provide decoded control information and system information to a controller/processor 280. The term “controller/processor” may refer to one or more controllers, one or more processors, or a combination thereof. A channel processor may determine a reference signal received power (RSRP) parameter, a received signal strength indicator (RSSI) parameter, a reference signal received quality (RSRQ) parameter, or a CQI parameter, among other examples. In some examples, one or more components of the UE 120 may be included in a housing.

The network controller 130 may include a communication unit 294, a controller/processor 290, and a memory 292. The network controller 130 may include, for example, one or more devices in a core network. The network controller 130 may communicate with the network node 110 via the communication unit 294.

One or more antennas (for example, antennas 234a through 234t or antennas 252a through 252r) may include, or may be included within, one or more antenna panels, one or more antenna groups, one or more sets of antenna elements, or one or more antenna arrays, among other examples. An antenna panel, an antenna group, a set of antenna elements, or an antenna array may include one or more antenna elements (within a single housing or multiple housings), a set of coplanar antenna elements, a set of non-coplanar antenna elements, or one or more antenna elements coupled to one or more transmission or reception components, such as one or more components of FIG. 2.

On the uplink, at the UE 120, a transmit processor 264 may receive and process data from a data source 262 and control information (for example, for reports that include RSRP, RSSI, RSRQ, or CQI) from the controller/processor 280. The transmit processor 264 may generate reference symbols for one or more reference signals. The symbols from the transmit processor 264 may be precoded by a TX MIMO processor 266 if applicable, further processed by the modems 254 (for example, for DFT-s-OFDM or CP-OFDM), and transmitted to the network node 110. In some examples, the modem 254 of the UE 120 may include a modulator and a demodulator. In some examples, the UE 120 includes a transceiver. The transceiver may include any combination of the antenna(s) 252, the modem(s) 254, the MIMO detector 256, the receive processor 258, the transmit processor 264, or the TX MIMO processor 266. The transceiver may be used by a processor (for example, the controller/processor 280) and the memory 282 to perform aspects of any of the processes described herein.

At the network node 110, the uplink signals from UE 120 or other UEs may be received by the antennas 234, processed by the modem 232 (for example, a demodulator component, shown as DEMOD, of the modem 232), detected by a MIMO detector 236 if applicable, and further processed by a receive processor 238 to obtain decoded data and control information sent by the UE 120. The receive processor 238 may provide the decoded data to a data sink 239 and provide the decoded control information to the controller/processor 240. The network node 110 may include a communication unit 244 and may communicate with the network controller 130 via the communication unit 244. The network node 110 may include a scheduler 246 to schedule one or more UEs 120 for downlink or uplink communications. In some examples, the modem 232 of the network node 110 may include a modulator and a demodulator. In some examples, the network node 110 includes a transceiver. The transceiver may include any combination of the antenna(s) 234, the modem(s) 232, the MIMO detector 236, the receive processor 238, the transmit processor 220, or the TX MIMO processor 230. The transceiver may be used by a processor (for example, the controller/processor 240) and the memory 242 to perform aspects of any of the processes described herein.

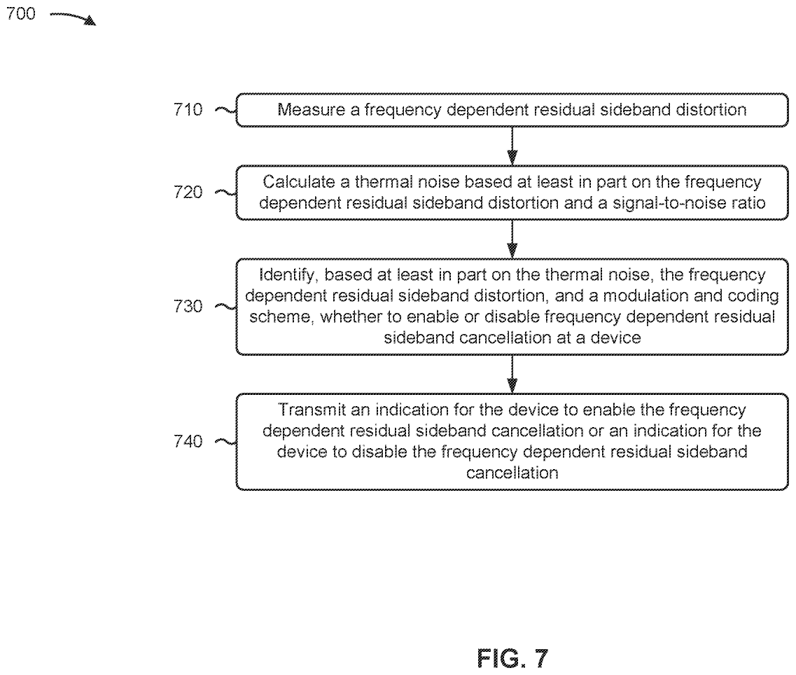

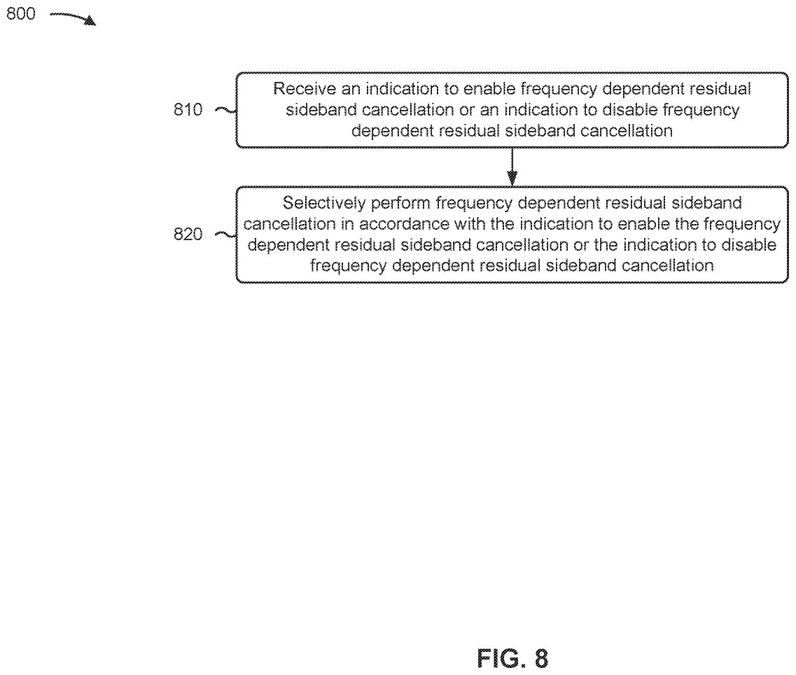

The controller/processor 240 of the network node 110, the controller/processor 280 of the UE 120, and/or any other component(s) of FIG. 2 may perform one or more techniques associated with frequency dependent residual sideband distortion cancellation, as described in more detail elsewhere herein. For example, the controller/processor 240 of the network node 110, the controller/processor 280 of the UE 120, and/or any other component(s) of FIG. 2 may perform or direct operations of, for example, process 700 of FIG. 7, process 800 of FIG. 8, and/or other processes as described herein. The memory 242 and the memory 282 may store data and program codes for the network node 110 and the UE 120, respectively. In some examples, the memory 242 and/or the memory 282 may include a non-transitory computer-readable medium storing one or more instructions (e.g., code and/or program code) for wireless communication. For example, the one or more instructions, when executed (e.g., directly, or after compiling, converting, and/or interpreting) by one or more processors of the network node 110 and/or the UE 120, may cause the one or more processors, the UE 120, and/or the network node 110 to perform or direct operations of, for example, process 700 of FIG. 7, process 800 of FIG. 8, and/or other processes as described herein. In some examples, executing instructions may include running the instructions, converting the instructions, compiling the instructions, and/or interpreting the instructions, among other examples.

In some aspects, the network node 110 includes means for measuring a frequency dependent residual sideband distortion; means for calculating a thermal noise based at least in part on the frequency dependent residual sideband distortion and a signal-to-noise ratio, means for identifying, based at least in part on the thermal noise, the frequency dependent residual sideband distortion, and a modulation and coding scheme, whether to enable or disable frequency dependent residual sideband cancellation at a device; and/or means for transmitting an indication for the device to enable the frequency dependent residual sideband cancellation or an indication for the device to disable the frequency dependent residual sideband cancellation. The means for the network node 110 to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246.

In some aspects, the UE 120 includes means for receiving an indication to enable frequency dependent residual sideband cancellation or an indication to disable frequency dependent residual sideband cancellation; and/or means for selectively performing frequency dependent residual sideband cancellation in accordance with the indication to enable the frequency dependent residual sideband cancellation or the indication to disable frequency dependent residual sideband cancellation. The means for the UE 120 to perform operations described herein may include, for example, one or more of communication manager 140, antenna 252, modem 254, MIMO detector 256, receive processor 258, transmit processor 264, TX MIMO processor 266, controller/processor 280, or memory 282.

In some aspects, an individual processor may perform all of the functions described as being performed by the one or more processors. In some aspects, one or more processors may collectively perform a set of functions. For example, a first set of (one or more) processors of the one or more processors may perform a first function described as being performed by the one or more processors, and a second set of (one or more) processors of the one or more processors may perform a second function described as being performed by the one or more processors. The first set of processors and the second set of processors may be the same set of processors or may be different sets of processors. Reference to “one or more processors” should be understood to refer to any one or more of the processors described in connection with FIG. 2. Reference to “one or more memories” should be understood to refer to any one or more memories of a corresponding device, such as the memory described in connection with FIG. 2. For example, functions described as being performed by one or more memories can be performed by the same subset of the one or more memories or different subsets of the one or more memories.

While blocks in FIG. 2 are illustrated as distinct components, the functions described above with respect to the blocks may be implemented in a single hardware, software, or combination component or in various combinations of components. For example, the functions described with respect to the transmit processor 264, the receive processor 258, and/or the TX MIMO processor 266 may be performed by or under the control of the controller/processor 280.

As indicated above, FIG. 2 is provided as an example. Other examples may differ from what is described with regard to FIG. 2.

Deployment of communication systems, such as 5G NR systems, may be arranged in multiple manners with various components or constituent parts. In a 5G NR system, or network, a network node, a network entity, a mobility element of a network, a RAN node, a core network node, a network element, a base station, or a network equipment may be implemented in an aggregated or disaggregated architecture. For example, a base station (such as a Node B (NB), an evolved NB (eNB), an NR base station, a 5G NB, an access point (AP), a TRP, or a cell, among other examples), or one or more units (or one or more components) performing base station functionality, may be implemented as an aggregated base station (also known as a standalone base station or a monolithic base station) or a disaggregated base station. “Network entity” or “network node” may refer to a disaggregated base station, or to one or more units of a disaggregated base station (such as one or more CUs, one or more DUs, one or more RUs, or a combination thereof).

An aggregated base station (e.g., an aggregated network node) may be configured to utilize a radio protocol stack that is physically or logically integrated within a single RAN node (for example, within a single device or unit). A disaggregated base station (e.g., a disaggregated network node) may be configured to utilize a protocol stack that is physically or logically distributed among two or more units (such as one or more CUs, one or more DUs, or one or more RUs). In some examples, a CU may be implemented within a network node, and one or more DUs may be co-located with the CU, or alternatively, may be geographically or virtually distributed throughout one or multiple other network nodes. The DUs may be implemented to communicate with one or more RUs. Each of the CU, DU, and RU also can be implemented as virtual units, such as a virtual central unit (VCU), a virtual distributed unit (VDU), or a virtual radio unit (VRU), among other examples.

Base station-type operation or network design may consider aggregation characteristics of base station functionality. For example, disaggregated base stations may be utilized in an IAB network, an open radio access network (O-RAN (such as the network configuration sponsored by the O-RAN Alliance)), or a virtualized radio access network (vRAN, also known as a cloud radio access network (C-RAN)) to facilitate scaling of communication systems by separating base station functionality into one or more units that can be individually deployed. A disaggregated base station may include functionality implemented across two or more units at various physical locations, as well as functionality implemented for at least one unit virtually, which can enable flexibility in network design. The various units of the disaggregated base station can be configured for wired or wireless communication with at least one other unit of the disaggregated base station.

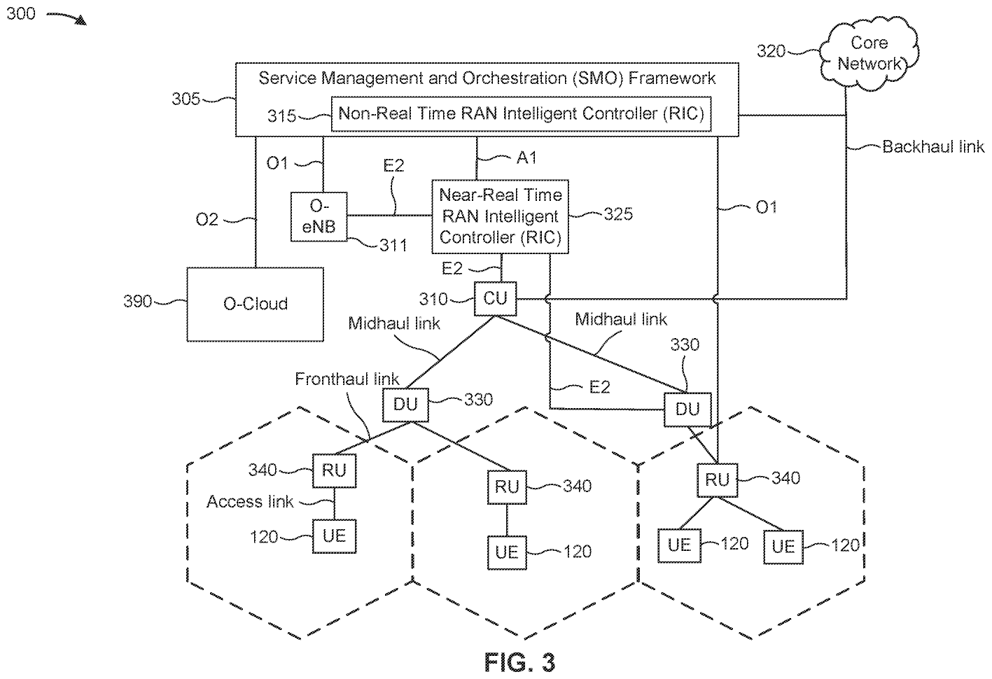

FIG. 3 is a diagram illustrating an example disaggregated base station architecture 300. The disaggregated base station architecture 300 may include a CU 310 that can communicate directly with a core network 320 via a backhaul link, or indirectly with the core network 320 through one or more disaggregated control units (such as a Near-RT RIC 325 via an E2 link, or a Non-RT RIC 315 associated with a Service Management and Orchestration (SMO) Framework 305, or both). A CU 310 may communicate with one or more DUs 330 via respective midhaul links, such as through F1 interfaces. Each of the DUs 330 may communicate with one or more RUs 340 via respective fronthaul links. Each of the RUs 340 may communicate with one or more UEs 120 via respective radio frequency (RF) access links. In some implementations, a UE 120 may be simultaneously served by multiple RUs 340.

Each of the units, including the CUs 310, the DUs 330, the RUs 340, as well as the Near-RT RICs 325, the Non-RT RICs 315, and the SMO Framework 305, may include one or more interfaces or be coupled with one or more interfaces configured to receive or transmit signals, data, or information (collectively, signals) via a wired or wireless transmission medium. Each of the units, or an associated processor or controller providing instructions to one or multiple communication interfaces of the respective unit, can be configured to communicate with one or more of the other units via the transmission medium. In some examples, each of the units can include a wired interface, configured to receive or transmit signals over a wired transmission medium to one or more of the other units, and a wireless interface, which may include a receiver, a transmitter or transceiver (such as a RF transceiver), configured to receive or transmit signals, or both, over a wireless transmission medium to one or more of the other units.

In some aspects, the CU 310 may host one or more higher layer control functions. Such control functions can include radio resource control (RRC) functions, packet data convergence protocol (PDCP) functions, or service data adaptation protocol (SDAP) functions, among other examples. Each control function can be implemented with an interface configured to communicate signals with other control functions hosted by the CU 310. The CU 310 may be configured to handle user plane functionality (for example, Central Unit-User Plane (CU-UP) functionality), control plane functionality (for example, Central Unit-Control Plane (CU-CP) functionality), or a combination thereof. In some implementations, the CU 310 can be logically split into one or more CU-UP units and one or more CU-CP units. A CU-UP unit can communicate bidirectionally with a CU-CP unit via an interface, such as the E1 interface when implemented in an O-RAN configuration. The CU 310 can be implemented to communicate with a DU 330, as necessary, for network control and signaling.

Each DU 330 may correspond to a logical unit that includes one or more base station functions to control the operation of one or more RUs 340. In some aspects, the DU 330 may host one or more of a radio link control (RLC) layer, a medium access control (MAC) layer, and one or more high physical (PHY) layers depending, at least in part, on a functional split, such as a functional split defined by the 3GPP. In some aspects, the one or more high PHY layers may be implemented by one or more modules for forward error correction (FEC) encoding and decoding, scrambling, and modulation and demodulation, among other examples. In some aspects, the DU 330 may further host one or more low PHY layers, such as implemented by one or more modules for a fast Fourier transform (FFT), an inverse FFT (iFFT), digital beamforming, or physical random access channel (PRACH) extraction and filtering, among other examples. Each layer (which also may be referred to as a module) can be implemented with an interface configured to communicate signals with other layers (and modules) hosted by the DU 330, or with the control functions hosted by the CU 310.

Each RU 340 may implement lower-layer functionality. In some deployments, an RU 340, controlled by a DU 330, may correspond to a logical node that hosts RF processing functions or low-PHY layer functions, such as performing an FFT, performing an iFFT, digital beamforming, or PRACH extraction and filtering, among other examples, based on a functional split (for example, a functional split defined by the 3GPP), such as a lower layer functional split. In such an architecture, each RU 340 can be operated to handle over the air (OTA) communication with one or more UEs 120. In some implementations, real-time and non-real-time aspects of control and user plane communication with the RU(s) 340 can be controlled by the corresponding DU 330. In some scenarios, this configuration can enable each DU 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements, which may be managed via an operations and maintenance interface (such as an O1 interface).

For virtualized network elements, the SMO Framework 305 may be configured to interact with a cloud computing platform (such as an open cloud (O-Cloud) platform 390) to perform network element life cycle management (such as to instantiate virtualized network elements) via a cloud computing platform interface (such as an O2 interface). Such virtualized network elements can include, but are not limited to, CUs 310. DUs 330, RUs 340, non-RT RICs 315, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with each of one or more RUs 340 via a respective O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (such as via an A1 interface) the Near-RT RIC 325. The Near-RT RIC 325 may be configured to include a logical function that enables near-real-time control and optimization of RAN elements and resources via data collection and actions over an interface (such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (such as reconfiguration via an O1 interface) or via creation of RAN management policies (such as A1 interface policies).

As indicated above, FIG. 3 is provided as an example. Other examples may differ from what is described with regard to FIG. 3.

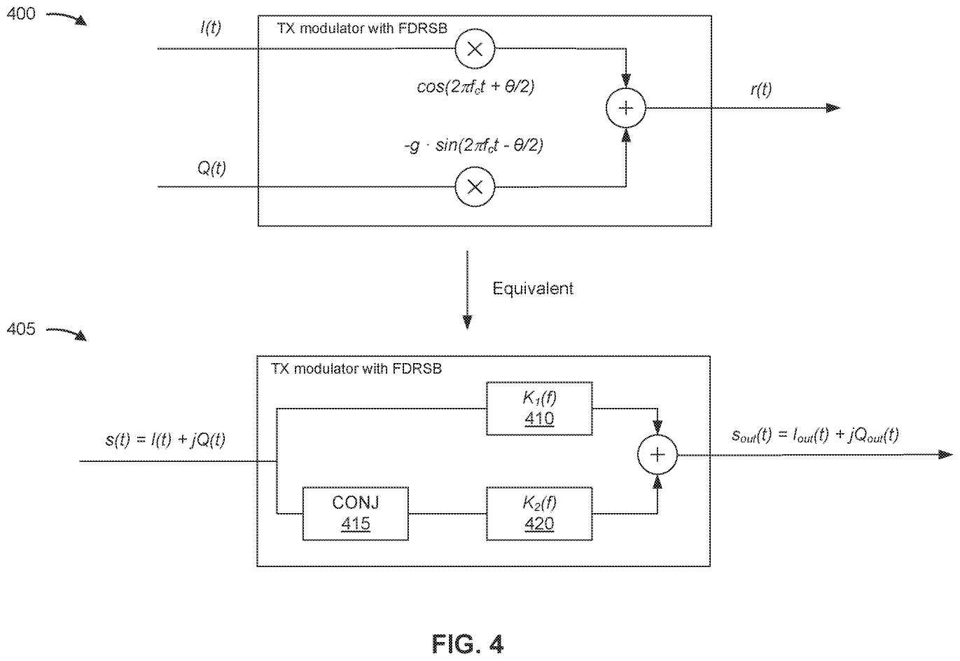

FIG. 4 is a diagram illustrating examples of frequency dependent residual sideband impairment. FDRSB impairment may be caused by a signal transmission mismatch (such as a quadrature signal (IQ signal) mismatch), and may result in radio frequency impairments that limit data transmission rates. FDRSB impairment may become more significant as carrier frequency increases. When transmissions are performed using MIMO communications, FDRSB may increase in accordance with the number of transmission antennas. In some cases, FDRSB may be calibrated at a network node to enable transmission of legacy QAM signals (e.g., up to 250 QAM). In order to achieve this transmission rate, the FDRSB impairment may be calibrated to be below 30 dBc. However, in order to approach superQAM modulation transmission rates (e.g., up to 16 thousand (16K) QAM), the FDRSB power may need to be lower (e.g., significantly lower) than 30 dBc. Thus, FDRSB mitigation may be needed in order to achieve superQAM modulations.

As shown in the example 400, FDRSB impairment may be caused by a lack of synchronization between an in-phase mixer and a quadrature mixer. A Tx modulator with FDRSB may receive an in-phase signal I(t) and a quadrature signal Q(t). The in-phase signal may be input to a first multiplier to obtain cos(2πf_{c}t+θ/2), and the quadrature signal may input to a second multiplier to obtain −g*cos(2πf_{c}t−θ/2), where fc is a frequency indicator, t is a time indicator, g is a gain offset, and θ is a phase offset. The output of the first multiplier and the output of the second multiplier may be input into an adder to obtain an output signal r(t).

As shown in the example 405, an equivalent baseband FDRSB impairment model may be generated in accordance with one or more parameters. A TX modulator with FDRSB may receive an input signal s(t)=I(t)+jQ(t), where I(t) is an in-phase component of the input signal and Q(t) is a quadrature component of the input signal. The input signal may be input into a first function K₁(f) 410 to obtain a first output. The input signal may be input into a conjugate function (CONJ) 415 to obtain a conjugate of the input signal, and the conjugate of the input signal may be input into a second function K₂(f) 420 to obtain a second output. The first output and the second output may be input to an adder function, and an output of the adder function may be an output signal sₒᵤₜ(t)=Iₒᵤₜ(t)+jQₒᵤₜ(t), where sₒᵤₜ is the output signal, Iₒᵤₜ is the in-phase component of the output signal, and Qₒᵤₜ is the quadrature component of the output signal. In this example,

$${K}_{1} ( f ) = 1 + g ( f ) {e}^{j θ ( f )}$$

$$and$$

$${K}_{2} ( f ) = 1 - g ( f ) {e}^{j θ ( f )} .$$

Thus, for every Tx input signal sᵢₙ(f):

$$\begin{matrix}{s}_{out} ( f ) = {K}_{1} ( f ) \cdot {s}_{in} ( f ) + {K}_{2} ( f ) \cdot {s}_{in}^{*} ( - f ) \\ = {K}_{1} ( f ) ( {s}_{in} ( f ) + \frac{{K}_{2} ( f )}{{K}_{1} ( f )} \cdot {s}_{in}^{*} ( - f ) ) ,\end{matrix}$$

$$where$$

$$\frac{{K}_{2} ( f )}{{K}_{1} ( f )}$$

is the FDRSB impairment of the channel, and the multiplication by K₁(f) is considered part of the channel.

Some UEs may be configured to estimate the FDRSB and to cancel the FDRSB. In this case, FDRSB cancellation may be performed regardless of the FDRSB power, for example, since the UE may not be able to identify whether the channel noise is cause by thermal noise (or mostly thermal noise) or by FDRSB noise (or mostly FDRSB noise). The FDRSB cancellation process at the UE may include estimating the experienced FDRSB, and removing the FDRSB based at least in part on the estimate of the FDRSB. This process may incur high complexity, may increase digital power consumption, and may increase latency at the UE demodulator. In some cases, such as when the channel noise results largely from thermal noise and/or when an estimated SNR is sufficient for demodulating a current MCS, the high-complexity FDRSB cancellation process may not be necessary, thereby resulting in wasted UE processing and energy resources, as well as increased latency.

Various aspects are described herein for FDRSB cancellation. A network node may measure an FDRSB distortion. The network node may calculate a thermal noise based at least in part on the FDRSB distortion and an SNR In some examples, calculating the thermal noise based at least in part on the FDRSB may include obtaining a quotient by dividing an SNR received from a UE from one, and subtracting the measured FDRSB distortion from the quotient. The network node may identify, based at least in part on the thermal noise, the FDRSB, and the MCS, whether to enable or disable FDRSB cancellation at the UE. The network node may generate an FDRSB cancellation message that indicates to enable the FDRSB cancellation at the UE or that indicates to disable the FDRSB cancellation at the UE. For example, the network node may generate an FDRSB cancellation message that indicates to enable the FDRSB cancellation at the UE in accordance with identifying to enable the FDRSB cancellation at the UE, or may generate an FDRSB cancellation message that indicates to disable the FDRSB cancellation at the UE in accordance with identifying the disable the FDRSB cancellation at the UE. The network node may transmit, and the UE may receive, the FDRSB cancellation message, and the UE may selectively perform FDRSB cancellation based at least in part on the FDRSB cancellation message. By determining, at the network node, whether FDRSB cancellation is to be performed, and by transmitting the FDRSB cancellation message to the UE indicating whether the FDRSB is to be performed by the UE, UE processing resources and energy consumption may be reduced, and latency may be improved. For example, the UE may refrain from performing FDRSB cancellation in accordance with the network node identifying that a channel noise results largely from thermal noise, and/or in accordance with the network node identifying that an estimated SNR is sufficient for demodulating a current MCS.

As indicated above, FIG. 4 is provided as an example. Other examples may differ from what is described with regard to FIG. 4.

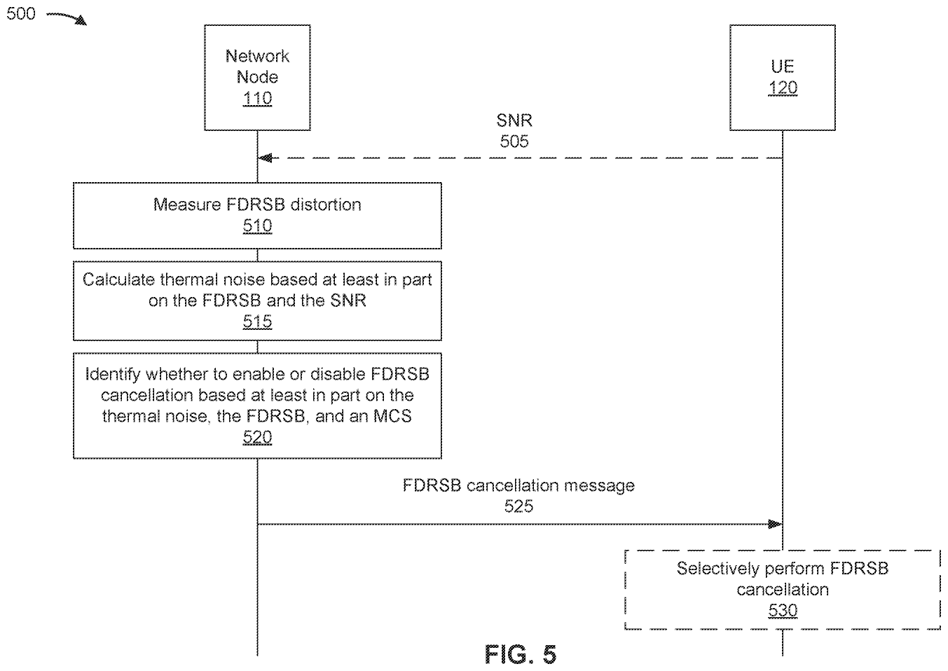

FIG. 5 is a diagram illustrating an example 500 of frequency dependent residual sideband cancellation.

At 505, the UE 120 may transmit, and the network node 110 may receive, an SNR. The SNR may be based at least in part on a CSI-RS (or a plurality of CSI-RSs). For example, the UE 120 may receive a CSI-RS from the network node 110, perform one or more CSI-RS measurements using the CSI-RS, calculate an SNR based at least in part on the one or more CSI-RS measurements, and transmit an indication of the SNR to the network node 110.

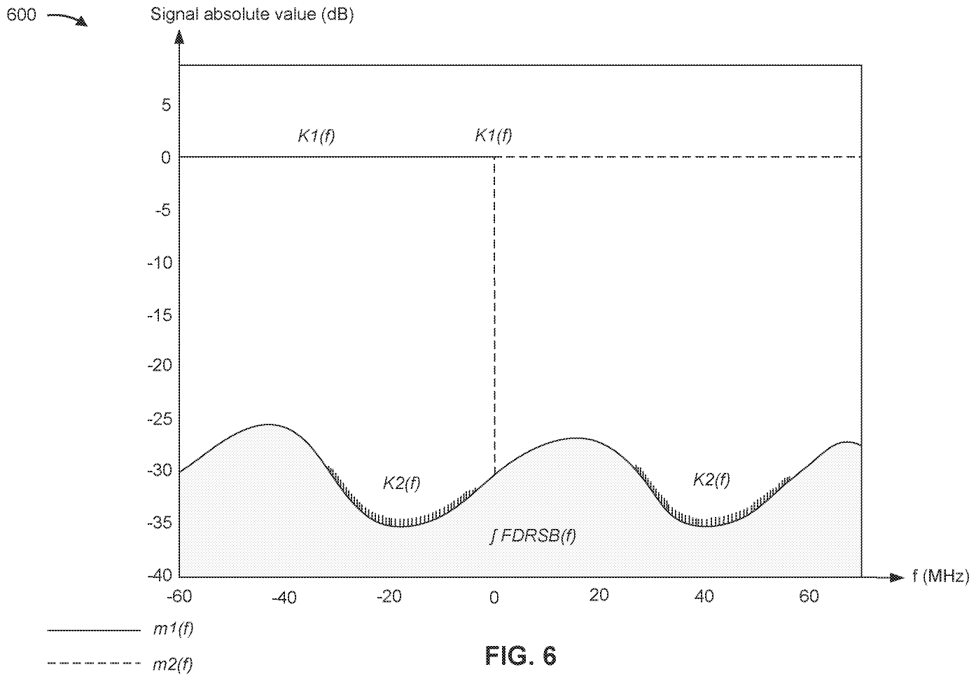

At 510, the network node 110 may measure an FDRSB. Measuring the FDRSB may include measuring an FDRSB distortion level (e.g., an FDRSB impairment) in dB. In one example, the network node 110 may measure the FDRSB in accordance with a step function and using two half-band signals. Additional details regarding these features are described in connection with FIG. 6.

At 515, the network node 110 may calculate a thermal noise based at least in part on the FDRSB and the SNR. In some aspects, the network node 110 may calculate a total noise in accordance with the following (e.g., assuming no other RF impairments or interference besides the FDRSB):
Total noise=Thermal noise level+FDRSB distortion level.

In some aspects, the network node 110 may measure the SNR as reported in a channel state feedback (CSF) report:

$$SNR = \frac{{σ}_{x}^{2}}{{σ}_{FDRSB}^{2} + {σ}_{Thermal}^{2}} \to \frac{1}{SNR} \to \frac{{σ}_{FDRSB}^{2}}{{σ}_{x}^{2}} + \frac{{σ}_{Thermal}^{2}}{{σ}_{x}^{2}} ,$$

where
σₓ² is a total noise level,
σ_{FDRSB}² is an FDRSB distortion level, and
σ_{Thermal}² is a thermal noise level.

In this example, the total thermal noise can be evaluated as:
1/reported SNR.

In some aspects, a signal power can be assumed to be 1 (0 dB), and extracting the thermal noise level from the FDRSB and the reported SNR (where the SNR is reported in every CSF report) may be represented as follows:

$$Thermal noise level = \frac{1}{reported SNR} - FDRSB distortion level = \frac{{σ}_{Thermal}^{2}}{{σ}_{x}^{2}} = {σ}_{Thermal}^{2} .$$

In some aspects, there may be other impairments in addition to the FDRSB impairment. In this case, the network node 110 may measure (and/or estimate) the other impairments and may subtract the other impairments from the total noise.

At 520, the network node 110 may identify whether to enable FDRSB cancellation or to disable FDRSB cancellation. The network node 110 may identify whether to enable the FDRSB cancellation or to disable the FDRSB cancellation based at least in part on the measured FDRSB, the SNR, and an MCS (e.g., an operating MCS). In some aspects, the network node 110 may identify to enable the FDRSB cancellation based at least in part on an FDRSB average power being less than an estimated thermal noise by a first threshold (TH1) (e.g., σ_{FDRSB}²<θ_{Thermal}²+TH1) or based at least in part on a measured SNR (before applying FDRSB correction) being sufficient for MCS decoding (e.g., SNR>ThresholdSNR+TH2).

In one example, the network node 110 may identify to enable the FDRSB cancellation based at least in part on the FDRSB average power being less than the estimated thermal noise by the threshold. Alternatively, the network node 110 may identify to disable the FDRSB cancellation based at least in part on the FDRSB average power being greater than or equal to the estimated thermal noise plus the threshold. In an example where the estimated thermal noise is higher than the average FDRSB level (measured by the network node 110), FDRSB mitigation may only have a minor effect (or may have no effect) on an error vector magnitude (EVM). However, estimating and cancelling the FDRSB may consume digital power and/or may increase latency. Therefore, the FDRSB estimation and cancellation may be a waste of UE processing and energy resources, and the network node 110 may transmit a message to the UE 120 for the UE 120 to disable the FDRSB cancellation.

In another example, the network node 110 may be configured (for each MCS) with a threshold SNR that is used to decode the MCS. If the reported SNR is already greater than the threshold EVM (e.g., by a second threshold (TH2) [dB] or more), the network node 110 may disable the FDRSB cancellation. In this example, the network node 110 may identify to enable the FDRSB cancellation based at least in part on the measured SNR (before applying FDRSB correction) being sufficient for the MCS decoding (e.g., based at least in part on the SNR being greater than the threshold SNR plus the second threshold). Alternatively, the network node 110 may identify to disable the FDRSB cancellation based at least in part on the measured SNR (before applying FDRSB correction) not being sufficient for the MCS decoding (e.g., based at least in part on the SNR being less than or equal to the threshold SNR plus the second threshold). In this example, the measured thermal noise (before FDRSB correction) may be sufficient, and thus, the FDRSB cancellation may be unnecessary. In some examples, the threshold SNRs may be determined offline and/or for each MCS of a plurality of MCS.

At 525, the network node 110 may transmit an indication for the UE 120 to enable FDRSB cancellation, or may transmit an indication for the UE 120 to disable FDRSB cancellation. In some aspects, the indication may be included in an FDRSB cancellation message. For example, the network node 110 may transmit, and the UE 120 may receive, based at least in part on the network node 110 identifying to enable the FDRSB cancellation, an FDRSB cancellation message that indicates for the UE 120 to enable the FDRSB cancellation. Alternatively, the network node 110 may transmit, and the UE 120 may receive, based at least in part on the network node 110 identifying to disable the FDRSB cancellation, an FDRSB cancellation message that indicates for the UE 120 to disable the FDRSB cancellation. In some aspects, the network node 110 may transmit the indication via a physical downlink control channel (PDCCH) message. For example, the network node 110 may transmit, and the UE 120 may receive, a PDCCH message that includes the FDRSB cancellation message that indicates for the UE 120 to enable FDRSB cancellation (or that indicates for the UE 120 to disable FDRSB cancellation). In some aspects, the indication to enable the FDRSB cancellation (or to disable the FDRSB cancellation) may be included in a single bit of the PDCCH message.

At 530, the UE 120 may perform FDRSB cancellation in accordance with the indication. For example, the UE 120 may perform the FDRSB cancellation based at least in part on receiving an FDRSB cancellation message that indicates for the UE 120 to enable FDRSB cancellation. Alternatively, the UE 120 may refrain from performing FDRSB cancellation based at least in part on receiving an FDRSB cancellation message that indicates for the UE 120 to disable FDRSB cancellation. The FDRSB cancellation may be performed as part of a demodulation process. For example, the UE 120, to perform the FDRSB cancellation, may perform the FDRSB cancellation during a demodulation process of the UE 120.

As indicated above, FIG. 5 is provided as an example. Other examples may differ from what is described with regard to FIG. 5.

FIG. 6 is a diagram illustrating an example 600 of a frequency dependent residual sideband measurement. This figure and description illustrate one example of performing FDRSB measurements. Any other FDRSB measurement techniques may be used to obtain an FDRSB value.

A network node may identify a step function u(t) with the following characteristics:

$$u ( f ) = \{ \begin{matrix}1 & f \geq 0 \\ 0 & f < 0\end{matrix} ,$$

where f is a measured frequency.

The network node may perform first measurement m1(f) in accordance with recording a half-band signal that is allocated on a left side of the bandwidth (BW) and that has a constant value of 0 dB over an entire subcarrier (e.g., u(−f) of the half-band signal. In this case, the measurement may indicate the following:

m₁(f)=K₁(f)·u(−f)+K₂(f)u(f), where
K₁(f) is a first function of a gain offset and a phase offset, and
K₂(f) is a second function of a gain offset and a phase offset.

The network node may perform a second measurement m2(f) in accordance with recording a half-band signal that is allocated on the right side of the BW and that has a constant value of 0 dB over an entire subcarrier (e.g., u(f)) of the half-band signal. In this case, the measurement may indicate the following:

$${m}_{2} ( f ) = {K}_{1} ( f ) \cdot u ( f ) + {K}_{2} ( f ) u ( - f ) .$$

The network node may calculate the average FDRSB in accordance with the following:

$${K}_{1} ( f ) = {m}_{1} ( f ) u ( - f ) + {m}_{2} ( f ) u ( f ) ,$$

$${K}_{2} ( f ) = {m}_{2} ( f ) u ( - f ) + {m}_{1} ( f ) u ( f ) ,$$

$$and$$

$$Average ( FDRSB ( f ) ) = \frac{1}{BW} \cdot {\int }_{BW} \frac{{K}_{2} ( f )}{{K}_{1} ( f )} df .$$

As indicated above, FIG. 6 is provided as an example. Other examples may differ from what is described with regard to FIG. 6.

FIG. 7 is a flowchart of an example method 700 of wireless communication.

The method 700 may be performed at, for example, a network node (e.g., network node 110) or an apparatus of a network node.

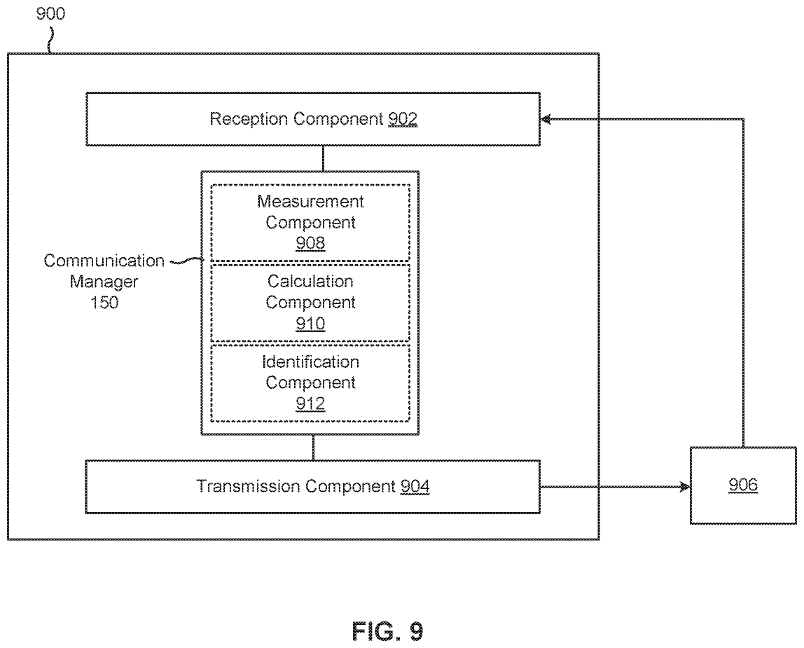

At 710, the network node may measure a frequency dependent residual sideband distortion. For example, the network node (e.g., using communication manager 150 and/or measurement component 908, depicted in FIG. 9) may measure a frequency dependent residual sideband distortion, as described above in connection with, for example, FIG. 5. In some aspects, measuring the frequency dependent residual sideband distortion comprises dividing a first parameter by a second parameter, the first parameter being based at least in part on subtracting a product of a gain offset and a phase offset from one, and the second parameter being based at least in part on adding one to the product of the gain offset and the phase offset.

At 720, the network node may calculate a thermal noise based at least in part on the frequency dependent residual sideband distortion and a signal-to-noise ratio. For example, the network node (e.g., using communication manager 150 and/or calculation component 910, depicted in FIG. 9) may calculate a thermal noise based at least in part on the frequency dependent residual sideband distortion and a signal-to-noise ratio, as described above in connection with, for example, FIG. 5. In some aspects, calculating the thermal noise based at least in part on the frequency dependent residual sideband distortion and the signal-to-noise ratio comprises calculating the thermal noise based at least in part on subtracting the frequency dependent residual sideband distortion from a quotient of one divided by the signal-to-noise ratio. In some aspects, the frequency dependent residual sideband distortion is based at least in part on a synchronization difference between an in-phase mixer and a quadrature mixer. In some aspects, calculating the thermal noise comprises calculating a total channel noise. In some aspects, calculating the thermal noise based at least in part on the frequency dependent residual sideband distortion and the signal-to-noise ratio comprises calculating the thermal noise based at least in part on the frequency dependent residual sideband distortion, the signal-to-noise ratio, and at least one other noise parameter.

At 730, the network node may identify, based at least in part on the thermal noise, the frequency dependent residual sideband distortion, and a modulation and coding scheme, whether to enable or disable frequency dependent residual sideband cancellation at a device. For example, the network node (e.g., using communication manager 150 and/or identification component 912, depicted in FIG. 9) may identify, based at least in part on the thermal noise, the frequency dependent residual sideband distortion, and a modulation and coding scheme, whether to enable or disable frequency dependent residual sideband cancellation at a device, as described above in connection with, for example, FIG. 5. In some aspects, method 700 includes generating, based at least in part on identifying whether to enable or disable the frequency dependent residual sideband cancellation at the device, a frequency dependent residual sideband cancellation message that indicates for the device to enable the frequency dependent residual sideband cancellation or that indicates for the device to disable the frequency dependent residual sideband cancellation, wherein transmitting the indication for the device to enable the frequency dependent residual sideband cancellation or the indication for the device to disable the frequency dependent residual sideband cancellation comprises transmitting, to the device, the frequency dependent residual sideband cancellation message that indicates for the device to enable the frequency dependent residual sideband cancellation or that indicates for the device to disable the frequency dependent residual sideband cancellation. In some aspects, identifying whether to enable or disable the frequency dependent residual sideband cancellation comprises identifying to disable the frequency dependent residual sideband cancellation based at least in part on a frequency dependent residual sideband power level being less than the thermal noise by a threshold amount. In some aspects, identifying whether to enable or disable the frequency dependent residual sideband cancellation comprises identifying to enable the frequency dependent residual sideband cancellation based at least in part on a frequency dependent residual sideband power level not being less than the thermal noise by a threshold amount. In some aspects, identifying whether to enable or disable the frequency dependent residual sideband cancellation comprises identifying to disable the frequency dependent residual sideband cancellation based at least in part on the signal-to-noise ratio being sufficient for decoding a signal using the modulation and coding scheme without applying the frequency dependent residual sideband cancellation. In some aspects, identifying whether to enable or disable the frequency dependent residual sideband cancellation comprises identifying to enable the frequency dependent residual sideband cancellation based at least in part on the signal-to-noise ratio not being sufficient for decoding a signal using the modulation and coding scheme without applying the frequency dependent residual sideband cancellation.

At 740, the network node may transmit an indication for the device to enable the frequency dependent residual sideband cancellation or an indication for the device to disable the frequency dependent residual sideband cancellation. For example, the network node (e.g., using communication manager 150 and/or transmission component 904, depicted in FIG. 9) may transmit an indication for the device to enable the frequency dependent residual sideband cancellation or an indication for the device to disable the frequency dependent residual sideband cancellation, as described above in connection with, for example. FIG. 5. In some aspects, method 700 includes receiving an indication of the signal-to-noise ratio from the device. In some aspects, transmitting the indication for the device to enable the frequency dependent residual sideband cancellation or to disable the frequency dependent residual sideband cancellation comprises transmitting a physical downlink control channel message that includes the indication for the device to enable the frequency dependent residual sideband cancellation or to disable the frequency dependent residual sideband cancellation. In some aspects, the indication for the device to enable the frequency dependent residual sideband cancellation or the indication for the device to disable the frequency dependent residual sideband cancellation is included in a single bit of the physical downlink control channel message.

Although FIG. 7 shows example blocks of method 700, in some aspects, method 700 may include additional blocks, fewer blocks, different blocks, or differently arranged blocks than those depicted in FIG. 7. Additionally, or alternatively, two or more of the blocks of method 700 may be performed in parallel.

FIG. 8 is a flowchart of an example method 800 of wireless communication. The method 800 may be performed at, for example, a UE (e.g., UE 120) or an apparatus of a UE.

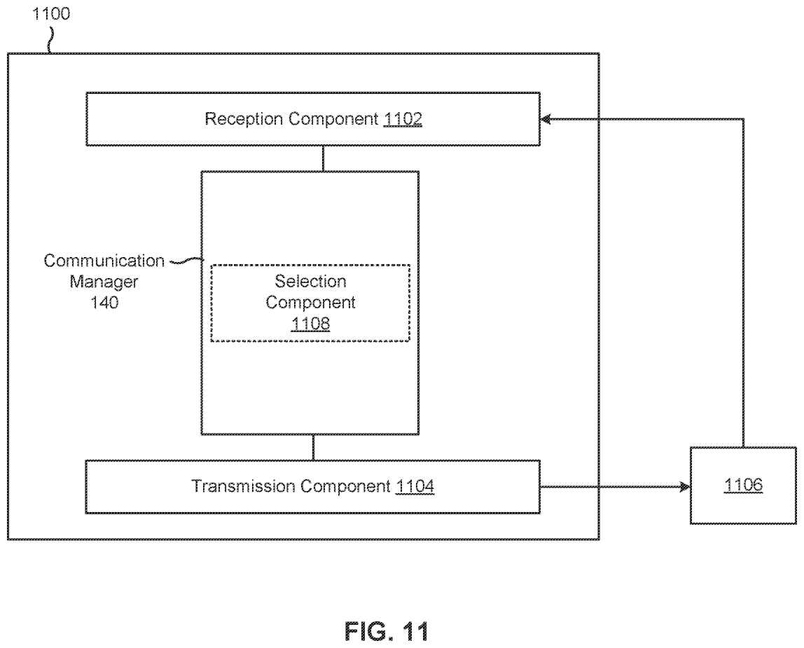

At 810, the UE may receive an indication to enable frequency dependent residual sideband cancellation or an indication to disable frequency dependent residual sideband cancellation. For example, the UE (e.g., using communication manager 140 and/or reception component 1102, depicted in FIG. 11) may receive an indication to enable frequency dependent residual sideband cancellation or an indication to disable frequency dependent residual sideband cancellation, as described above in connection with, for example, FIG. 5. In some aspects, receiving the indication to enable the frequency dependent residual sideband cancellation or the indication to disable the frequency dependent residual sideband cancellation comprises receiving a frequency dependent residual sideband cancellation message that indicates for the UE to enable the frequency dependent residual sideband cancellation or that indicates for the UE to disable the frequency dependent residual sideband cancellation. In some aspects, receiving the indication to enable the frequency dependent residual sideband cancellation or the indication to disable the frequency dependent residual sideband cancellation comprises receiving the indication to enable the frequency dependent residual sideband cancellation, and wherein selectively performing the frequency dependent residual sideband cancellation comprises performing the frequency dependent residual sideband cancellation based at least in part on receiving the indication to enable the frequency dependent residual sideband cancellation. In some aspects, receiving the indication to enable the frequency dependent residual sideband cancellation or the indication to disable the frequency dependent residual sideband cancellation comprises receiving the indication to disable the frequency dependent residual sideband cancellation, and wherein selectively performing the frequency dependent residual sideband cancellation comprises refraining from performing the frequency dependent residual sideband cancellation based at least in part on receiving the indication to disable the frequency dependent residual sideband cancellation. In some aspects, the indication to enable the frequency dependent residual sideband cancellation or the indication to disable the frequency dependent residual sideband cancellation is based at least on part on a thermal noise measurement, a frequency dependent residual sideband distortion measurement, and a modulation and coding scheme.

In some aspects, receiving the indication to enable the frequency dependent residual sideband cancellation or the indication to disable the frequency dependent residual sideband cancellation comprises receiving an indication to disable the frequency dependent residual sideband cancellation based at least in part on a frequency dependent residual sideband power level being less than a thermal noise by a threshold amount. In some aspects, receiving the indication to enable the frequency dependent residual sideband cancellation or to disable the frequency dependent residual sideband cancellation comprises receiving an indication to enable the frequency dependent residual sideband cancellation based at least in part on a frequency dependent residual sideband power level not being less than a thermal noise by a threshold amount. In some aspects, receiving the indication to enable the frequency dependent residual sideband cancellation or the indication to disable the frequency dependent residual sideband cancellation comprises receiving an indication to disable the frequency dependent residual sideband cancellation based at least in part on a signal-to-noise ratio being sufficient for decoding a signal using a modulation and coding scheme without applying the frequency dependent residual sideband cancellation. In some aspects, receiving the indication to enable the frequency dependent residual sideband cancellation or the indication to disable the frequency dependent residual sideband cancellation comprises receiving an indication to enable the frequency dependent residual sideband cancellation based at least in part on a signal-to-noise ratio not being sufficient for decoding a signal using a modulation and coding scheme without applying the frequency dependent residual sideband cancellation. In some aspects, receiving the indication to enable the frequency dependent residual sideband cancellation or the indication to disable the frequency dependent residual sideband cancellation comprises receiving a physical downlink control channel message that includes the indication to enable the frequency dependent residual sideband cancellation or that indicates to disable the frequency dependent residual sideband cancellation. In some aspects, the indication to enable the frequency dependent residual sideband cancellation or the indication to disable the frequency dependent residual sideband cancellation is included in a single bit of the physical downlink control channel message.

At 820, the UE may selectively perform frequency dependent residual sideband cancellation in accordance with the indication to enable the frequency dependent residual sideband cancellation or the indication to disable frequency dependent residual sideband cancellation. For example, the UE (e.g., using communication manager 140 and/or selection component 1108, depicted in FIG. 11) may selectively perform frequency dependent residual sideband cancellation in accordance with the indication to enable the frequency dependent residual sideband cancellation or the indication to disable frequency dependent residual sideband cancellation, as described above in connection with, for example. FIG. 5. In some aspects, selectively performing the frequency dependent residual sideband cancellation comprises selectively performing the frequency dependent residual sideband cancellation during a signal demodulation process performed by the UE. In some aspects, a frequency dependent residual sideband distortion associated with the frequency dependent residual sideband cancellation is based at least in part on a synchronization difference between an in-phase mixer and a quadrature mixer. In some aspects, method 800 includes transmitting an indication of a signal-to-noise ratio, wherein the indication to enable the frequency dependent residual sideband cancellation or the indication to disable the frequency dependent residual sideband cancellation is based at least on part on the signal-to-noise ratio.

Although FIG. 8 shows example blocks of method 800, in some aspects, method 800 may include additional blocks, fewer blocks, different blocks, or differently arranged blocks than those depicted in FIG. 8. Additionally, or alternatively, two or more of the blocks of method 800 may be performed in parallel.

FIG. 9 is a diagram of an example apparatus 900 for wireless communication. The apparatus 900 may be a network node, or a network node may include the apparatus 900. In some aspects, the apparatus 900 includes a reception component 902 and a transmission component 904, which may be in communication with one another (for example, via one or more buses and/or one or more other components). As shown, the apparatus 900 may communicate with another apparatus 906 (such as a UE, a base station, or another wireless communication device) using the reception component 902 and the transmission component 904. As further shown, the apparatus 900 may include the communication manager 150. The communication manager 150 may include one or more of a measurement component 908, a calculation component 910, or an identification component 912, among other examples.

In some aspects, the apparatus 900 may be configured to perform one or more operations described herein in connection with FIGS. 5-6. Additionally, or alternatively, the apparatus 900 may be configured to perform one or more processes described herein, such as process 700 of FIG. 7. In some aspects, the apparatus 900 and/or one or more components shown in FIG. 9 may include one or more components of the network node described in connection with FIG. 2. Additionally. or alternatively, one or more components shown in FIG. 9 may be implemented within one or more components described in connection with FIG. 2. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 902 may receive communications, such as reference signals, control information, data communications, or a combination thereof, from the apparatus 906. The reception component 902 may provide received communications to one or more other components of the apparatus 900. In some aspects, the reception component 902 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 900. In some aspects, the reception component 902 may include one or more antennas, one or more modems, one or more demodulators, one or more MIMO detectors, one or more receive processors, one or more controllers/processors, one or more memories, or a combination thereof, of the network node described in connection with FIG. 2.

The transmission component 904 may transmit communications, such as reference signals, control information, data communications, or a combination thereof, to the apparatus 906. In some aspects, one or more other components of the apparatus 900 may generate communications and may provide the generated communications to the transmission component 904 for transmission to the apparatus 906. In some aspects, the transmission component 904 may perform signal processing on the generated communications (such as filtering, amplification, modulation, digital-to-analog conversion, multiplexing, interleaving, mapping, or encoding, among other examples), and may transmit the processed signals to the apparatus 906. In some aspects, the transmission component 904 may include one or more antennas, one or more modems, one or more modulators, one or more transmit MIMO processors, one or more transmit processors, one or more controllers/processors, one or more memories, or a combination thereof, of the network node described in connection with FIG. 2. In some aspects, the transmission component 904 may be co-located with the reception component 902 in one or more transceivers.

The measurement component 908 may measure a frequency dependent residual sideband distortion. The calculation component 910 may calculate a thermal noise based at least in part on the frequency dependent residual sideband distortion and a signal-to-noise ratio. The identification component 912 may identify, based at least in part on the thermal noise, the frequency dependent residual sideband distortion, and a modulation and coding scheme, whether to enable or disable frequency dependent residual sideband cancellation at a device. The transmission component 904 may transmit an indication for the device to enable the frequency dependent residual sideband cancellation or an indication for the device to disable the frequency dependent residual sideband cancellation. The transmission component 904 may transmit, based at least in part on identifying whether to enable or disable the frequency dependent residual sideband cancellation at the device, a frequency dependent residual sideband cancellation message that indicates for the device to enable the frequency dependent residual sideband cancellation or that indicates for the device to disable the frequency dependent residual sideband cancellation. The reception component 902 may receive an indication of the signal-to-noise ratio from the device.

The number and arrangement of components shown in FIG. 9 are provided as an example. In practice, there may be additional components, fewer components, different components, or differently arranged components than those shown in FIG. 9. Furthermore, two or more components shown in FIG. 9 may be implemented within a single component, or a single component shown in FIG. 9 may be implemented as multiple, distributed components. Additionally, or alternatively, a set of(one or more) components shown in FIG. 9 may perform one or more functions described as being performed by another set of components shown in FIG. 9.

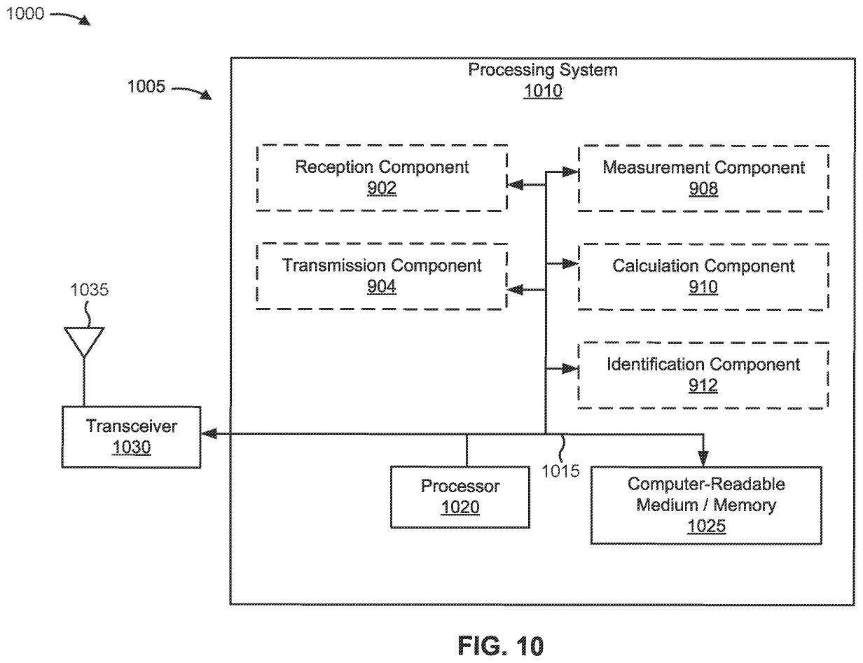

FIG. 10 is a diagram illustrating an example 1000 of a hardware implementation for an apparatus 1005 employing a processing system 1010. The apparatus 1005 may be a network node or may be at (e.g., included in) a network node.

The processing system 1010 may be implemented with a bus architecture, represented generally by the bus 1015. The bus 1015 may include any number of interconnecting buses and bridges depending on the specific application of the processing system 1010 and the overall design constraints. The bus 1015 links together various circuits including one or more processors and/or hardware components, represented by the processor 1020, the illustrated components, and the computer-readable medium/memory 1025. The bus 1015 may also link various other circuits, such as timing sources, peripherals, voltage regulators, and/or power management circuits.

The processing system 1010 may be coupled to one or more transceivers 1030. A transceiver 1030 is coupled to one or more antennas 1035. The transceiver 1030 provides a means for communicating with various other apparatuses over a transmission medium. The transceiver 1030 receives a signal from the one or more antennas 1035, extracts information from the received signal, and provides the extracted information to the processing system 1010, specifically the reception component 902. In addition, the transceiver 1030 receives information from the processing system 1010, specifically the transmission component 904, and generates a signal to be applied to the one or more antennas 1035 based at least in part on the received information.

The processing system 1010 includes one or more processors 1020 coupled to a computer-readable medium/memory 1025. A processor 1020 is responsible for general processing, including the execution of software stored on the computer-readable medium/memory 1025. The software, when executed by the processor 1020, causes the processing system 1010 to perform the various functions described herein for any particular apparatus. The computer-readable medium/memory 1025 may also be used for storing data that is manipulated by the processor 1020 when executing software. The processing system further includes at least one of the illustrated components. The components may be software modules running in the processor 1020, resident/stored in the computer-readable medium/memory 1025, one or more hardware modules coupled to the processor 1020, or some combination thereof.

In some aspects, the processing system 1010 may be a component of the base station 110 and may include one or more memories, such as the memory 242, and/or may include one or more processors, such as at least one of the TX MIMO processor 230, the receiver (RX) processor 238, and/or the controller/processor 240. In some aspects, the apparatus 1005 for wireless communication includes means for FDRSB cancellation The aforementioned means may be one or more of the aforementioned components of the apparatus 900 and/or the processing system 1010 of the apparatus 1005 configured to perform the functions recited by the aforementioned means. As described elsewhere herein, the processing system 1010 may include the TX MIMO processor 230, the receive processor 238, and/or the controller/processor 240. In one configuration, the aforementioned means may be the TX MIMO processor 230, the receive processor 238, and/or the controller/processor 240 configured to perform the functions and/or operations recited herein.

FIG. 10 is provided as an example. Other examples may differ from what is described in connection with FIG. 10.

FIG. 11 is a diagram of an example apparatus 1100 for wireless communication. The apparatus 1100 may be a UE, or a UE may include the apparatus 1100. In some aspects, the apparatus 1100 includes a reception component 1102 and a transmission component 1104, which may be in communication with one another (for example, via one or more buses and/or one or more other components). As shown, the apparatus 1100 may communicate with another apparatus 1106 (such as a UE, a base station, or another wireless communication device) using the reception component 1102 and the transmission component 1104. As further shown, the apparatus 1100 may include the communication manager 140. The communication manager 140 may include a selection component 1108, among other examples.

In some aspects, the apparatus 1100 may be configured to perform one or more operations described herein in connection with FIGS. 5-6. Additionally, or alternatively, the apparatus 1100 may be configured to perform one or more processes described herein, such as process 800 of FIG. 8. In some aspects, the apparatus 1100 and/or one or more components shown in FIG. 11 may include one or more components of the UE described in connection with FIG. 2. Additionally, or alternatively, one or more components shown in FIG. 11 may be implemented within one or more components described in connection with FIG. 2. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1102 may receive communications, such as reference signals, control information, data communications, or a combination thereof, from the apparatus 1106. The reception component 1102 may provide received communications to one or more other components of the apparatus 1100. In some aspects, the reception component 1102 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 1100. In some aspects, the reception component 1102 may include one or more antennas, one or more modems, one or more demodulators, one or more MIMO detectors, one or more receive processors, one or more controllers/processors, one or more memories, or a combination thereof, of the UE described in connection with FIG. 2.

The transmission component 1104 may transmit communications, such as reference signals, control information, data communications, or a combination thereof, to the apparatus 1106. In some aspects, one or more other components of the apparatus 1100 may generate communications and may provide the generated communications to the transmission component 1104 for transmission to the apparatus 1106. In some aspects, the transmission component 1104 may perform signal processing on the generated communications (such as filtering, amplification, modulation, digital-to-analog conversion, multiplexing, interleaving, mapping, or encoding, among other examples), and may transmit the processed signals to the apparatus 1106. In some aspects, the transmission component 1104 may include one or more antennas, one or more modems, one or more modulators, one or more transmit MIMO processors, one or more transmit processors, one or more controllers/processors, one or more memories, or a combination thereof, of the UE described in connection with FIG. 2. In some aspects, the transmission component 1104 may be co-located with the reception component 1102 in one or more transceivers.

The reception component 1102 may receive an indication to enable frequency dependent residual sideband cancellation or an indication to disable frequency dependent residual sideband cancellation. The selection component 1108 may selectively perform frequency dependent residual sideband cancellation in accordance with the indication to enable the frequency dependent residual sideband cancellation or the indication to disable frequency dependent residual sideband cancellation. The transmission component 1104 may transmit an indication of a signal-to-noise ratio, wherein the indication to enable the frequency dependent residual sideband cancellation or the indication to disable the frequency dependent residual sideband cancellation is based at least on part on the signal-to-noise ratio.

The number and arrangement of components shown in FIG. 11 are provided as an example. In practice, there may be additional components, fewer components, different components, or differently arranged components than those shown in FIG. 11. Furthermore, two or more components shown in FIG. 11 may be implemented within a single component, or a single component shown in FIG. 11 may be implemented as multiple, distributed components. Additionally, or alternatively, a set of(one or more) components shown in FIG. 11 may perform one or more functions described as being performed by another set of components shown in FIG. 11.

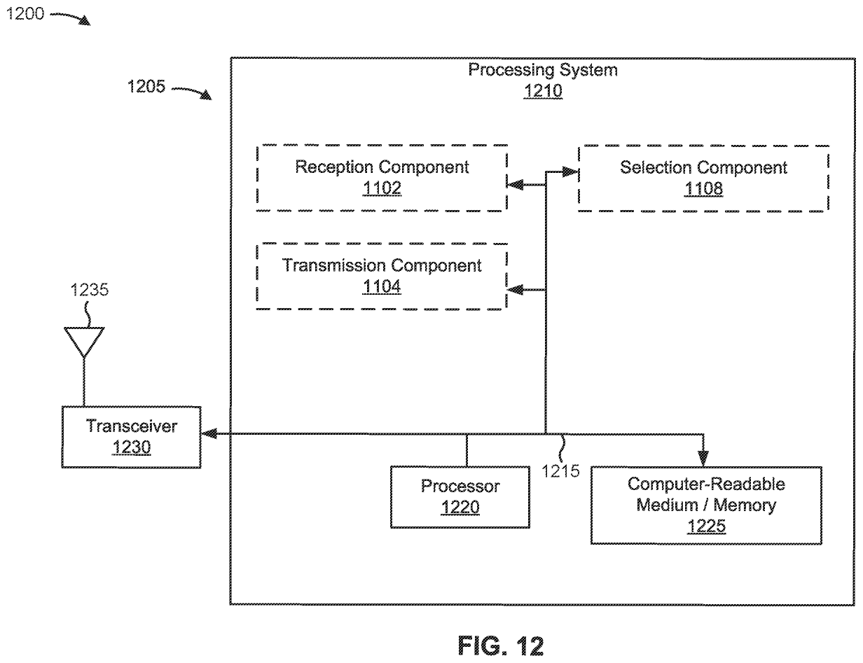

FIG. 12 is a diagram illustrating an example 1200 of a hardware implementation for an apparatus 1205 employing a processing system 1210. The apparatus 1205 may be a network node or may be at (e.g., included in) a network node.

The processing system 1210 may be implemented with a bus architecture, represented generally by the bus 1215. The bus 1215 may include any number of interconnecting buses and bridges depending on the specific application of the processing system 1210 and the overall design constraints. The bus 1215 links together various circuits including one or more processors and/or hardware components, represented by the processor 1220, the illustrated components, and the computer-readable medium/memory 1225. The bus 1215 may also link various other circuits, such as timing sources, peripherals, voltage regulators, and/or power management circuits.

The processing system 1210 may be coupled to one or more transceivers 1230. A transceiver 1230 is coupled to one or more antennas 1235. The transceiver 1230 provides a means for communicating with various other apparatuses over a transmission medium. The transceiver 1230 receives a signal from the one or more antennas 1235, extracts information from the received signal, and provides the extracted information to the processing system 1210, specifically the reception component 1102. In addition, the transceiver 1230 receives information from the processing system 1210, specifically the transmission component 1104, and generates a signal to be applied to the one or more antennas 1235 based at least in part on the received information.

The processing system 1210 includes one or more processors 1220 coupled to a computer-readable medium/memory 1225. A processor 1220 is responsible for general processing, including the execution of software stored on the computer-readable medium/memory 1225. The software, when executed by the processor 1220, causes the processing system 1210 to perform the various functions described herein for any particular apparatus. The computer-readable medium/memory 1225 may also be used for storing data that is manipulated by the processor 1220 when executing software. The processing system further includes at least one of the illustrated components. The components may be software modules running in the processor 1220, resident/stored in the computer-readable medium/memory 1225, one or more hardware modules coupled to the processor 1220, or some combination thereof.

In some aspects, the processing system 1210 may be a component of the UE 120 and may include one or more memories, such as the memory 282, and/or may include one or more processors, such as at least one of the TX MIMO processor 266, the RX processor 258, and/or the controller/processor 280. In some aspects, the apparatus 1205 for wireless communication includes means for FDRSB cancellation. The aforementioned means may be one or more of the aforementioned components of the apparatus 1100 and/or the processing system 1210 of the apparatus 1205 configured to perform the functions recited by the aforementioned means. As described elsewhere herein, the processing system 1210 may include the TX MIMO processor 266, the RX processor 258, and/or the controller/processor 280. In one configuration, the aforementioned means may be the TX MIMO processor 266, the RX processor 258, and/or the controller/processor 280 configured to perform the functions and/or operations recited herein.

FIG. 12 is provided as an example. Other examples may differ from what is described in connection with FIG. 12.

The following provides an overview of some Aspects of the present disclosure:

Aspect 1: A method of wireless communication performed by a network node, comprising: measuring a frequency dependent residual sideband distortion; calculating a thermal noise based at least in part on the frequency dependent residual sideband distortion and a signal-to-noise ratio; identifying, based at least in part on the thermal noise, the frequency dependent residual sideband distortion, and a modulation and coding scheme, whether to enable or disable frequency dependent residual sideband cancellation at a device; and transmitting an indication for the device to enable the frequency dependent residual sideband cancellation or an indication for the device to disable the frequency dependent residual sideband cancellation.

Aspect 2: The method of Aspect 1, further comprising generating, based at least in part on identifying whether to enable or disable the frequency dependent residual sideband cancellation at the device, a frequency dependent residual sideband cancellation message that indicates for the device to enable the frequency dependent residual sideband cancellation or that indicates for the device to disable the frequency dependent residual sideband cancellation, wherein transmitting the indication for the device to enable the frequency dependent residual sideband cancellation or the indication for the device to disable the frequency dependent residual sideband cancellation comprises transmitting, to the device, the frequency dependent residual sideband cancellation message that indicates for the device to enable the frequency dependent residual sideband cancellation or that indicates for the device to disable the frequency dependent residual sideband cancellation.

Aspect 3: The method of any of Aspects 1-2, wherein calculating the thermal noise based at least in part on the frequency dependent residual sideband distortion and the signal-to-noise ratio comprises calculating the thermal noise based at least in part on subtracting the frequency dependent residual sideband distortion from a quotient of one divided by the signal-to-noise ratio.

Aspect 4: The method of any of Aspects 1-3, wherein the frequency dependent residual sideband distortion is based at least in part on a synchronization difference between an in-phase mixer and a quadrature mixer.

Aspect 5: The method of any of Aspects 1-4, wherein measuring the frequency dependent residual sideband distortion comprises dividing a first parameter by a second parameter, the first parameter being based at least in part on subtracting a product of a gain offset and a phase offset from one, and the second parameter being based at least in part on adding one to the product of the gain offset and the phase offset.

Aspect 6: The method of any of Aspects 1-5, wherein calculating the thermal noise comprises calculating a total channel noise.

Aspect 7: The method of any of Aspects 1-6, wherein calculating the thermal noise based at least in part on the frequency dependent residual sideband distortion and the signal-to-noise ratio comprises calculating the thermal noise based at least in part on the frequency dependent residual sideband distortion, the signal-to-noise ratio, and at least one other noise parameter.

Aspect 8: The method of any of Aspects 1-7, wherein identifying whether to enable or disable the frequency dependent residual sideband cancellation comprises identifying to disable the frequency dependent residual sideband cancellation based at least in part on a frequency dependent residual sideband power level being less than the thermal noise by a threshold amount.

Aspect 9: The method of any of Aspects 1-8, wherein identifying whether to enable or disable the frequency dependent residual sideband cancellation comprises identifying to enable the frequency dependent residual sideband cancellation based at least in part on a frequency dependent residual sideband power level not being less than the thermal noise by a threshold amount.

Aspect 10: The method of any of Aspects 1-9, wherein identifying whether to enable or disable the frequency dependent residual sideband cancellation comprises identifying to disable the frequency dependent residual sideband cancellation based at least in part on the signal-to-noise ratio being sufficient for decoding a signal using the modulation and coding scheme without applying the frequency dependent residual sideband cancellation.

Aspect 11: The method of any of Aspects 1-10, wherein identifying whether to enable or disable the frequency dependent residual sideband cancellation comprises identifying to enable the frequency dependent residual sideband cancellation based at least in part on the signal-to-noise ratio not being sufficient for decoding a signal using the modulation and coding scheme without applying the frequency dependent residual sideband cancellation.

Aspect 12: The method of any of Aspects 1-11, further comprising receiving an indication of the signal-to-noise ratio from the device.

Aspect 13: The method of any of Aspects 1-12, wherein transmitting the indication for the device to enable the frequency dependent residual sideband cancellation or to disable the frequency dependent residual sideband cancellation comprises transmitting a physical downlink control channel message that includes the indication for the device to enable the frequency dependent residual sideband cancellation or to disable the frequency dependent residual sideband cancellation.

Aspect 14: The method of Aspect 13, wherein the indication for the device to enable the frequency dependent residual sideband cancellation or the indication for the device to disable the frequency dependent residual sideband cancellation is included in a single bit of the physical downlink control channel message.

Aspect 15: A method of wireless communication performed by a user equipment (UE), comprising: receiving an indication to enable frequency dependent residual sideband cancellation or an indication to disable frequency dependent residual sideband cancellation; and selectively performing frequency dependent residual sideband cancellation in accordance with the indication to enable the frequency dependent residual sideband cancellation or the indication to disable frequency dependent residual sideband cancellation.

Aspect 16: The method of Aspect 15, wherein receiving the indication to enable the frequency dependent residual sideband cancellation or the indication to disable the frequency dependent residual sideband cancellation comprises receiving a frequency dependent residual sideband cancellation message that indicates for the UE to enable the frequency dependent residual sideband cancellation or that indicates for the UE to disable the frequency dependent residual sideband cancellation.

Aspect 17: The method of any of Aspects 15-16, wherein receiving the indication to enable the frequency dependent residual sideband cancellation or the indication to disable the frequency dependent residual sideband cancellation comprises receiving the indication to enable the frequency dependent residual sideband cancellation, and wherein selectively performing the frequency dependent residual sideband cancellation comprises performing the frequency dependent residual sideband cancellation based at least in part on receiving the indication to enable the frequency dependent residual sideband cancellation.

Aspect 18: The method of any of Aspects 15-17, wherein receiving the indication to enable the frequency dependent residual sideband cancellation or the indication to disable the frequency dependent residual sideband cancellation comprises receiving the indication to disable the frequency dependent residual sideband cancellation, and wherein selectively performing the frequency dependent residual sideband cancellation comprises refraining from performing the frequency dependent residual sideband cancellation based at least in part on receiving the indication to disable the frequency dependent residual sideband cancellation.

Aspect 19: The method of any of Aspects 15-18, wherein the indication to enable the frequency dependent residual sideband cancellation or the indication to disable the frequency dependent residual sideband cancellation is based at least on part on a thermal noise measurement, a frequency dependent residual sideband distortion measurement, and a modulation and coding scheme.

Aspect 20: The method of any of Aspects 15-19, further comprising transmitting an indication of a signal-to-noise ratio, wherein the indication to enable the frequency dependent residual sideband cancellation or the indication to disable the frequency dependent residual sideband cancellation is based at least on part on the signal-to-noise ratio.

Aspect 21: The method of any of Aspects 15-20, wherein selectively performing the frequency dependent residual sideband cancellation comprises selectively performing the frequency dependent residual sideband cancellation during a signal demodulation process performed by the UE.

Aspect 22: The method of any of Aspects 15-21, wherein a frequency dependent residual sideband distortion associated with the frequency dependent residual sideband cancellation is based at least in part on a synchronization difference between an in-phase mixer and a quadrature mixer.

Aspect 23: The method of any of Aspects 15-22, wherein receiving the indication to enable the frequency dependent residual sideband cancellation or the indication to disable the frequency dependent residual sideband cancellation comprises receiving an indication to disable the frequency dependent residual sideband cancellation based at least in part on a frequency dependent residual sideband power level being less than a thermal noise by a threshold amount.

Aspect 24: The method of any of Aspects 15-23, wherein receiving the indication to enable the frequency dependent residual sideband cancellation or to disable the frequency dependent residual sideband cancellation comprises receiving an indication to enable the frequency dependent residual sideband cancellation based at least in part on a frequency dependent residual sideband power level not being less than a thermal noise by a threshold amount.

Aspect 25: The method of any of Aspects 15-24, wherein receiving the indication to enable the frequency dependent residual sideband cancellation or the indication to disable the frequency dependent residual sideband cancellation comprises receiving an indication to disable the frequency dependent residual sideband cancellation based at least in part on a signal-to-noise ratio being sufficient for decoding a signal using a modulation and coding scheme without applying the frequency dependent residual sideband cancellation.

Aspect 26: The method of any of Aspects 15-25, wherein receiving the indication to enable the frequency dependent residual sideband cancellation or the indication to disable the frequency dependent residual sideband cancellation comprises receiving an indication to enable the frequency dependent residual sideband cancellation based at least in part on a signal-to-noise ratio not being sufficient for decoding a signal using a modulation and coding scheme without applying the frequency dependent residual sideband cancellation.

Aspect 27: The method of any of Aspects 15-26, wherein receiving the indication to enable the frequency dependent residual sideband cancellation or the indication to disable the frequency dependent residual sideband cancellation comprises receiving a physical downlink control channel message that includes the indication to enable the frequency dependent residual sideband cancellation or that indicates to disable the frequency dependent residual sideband cancellation.

Aspect 28: The method of Aspect 27, wherein the indication to enable the frequency dependent residual sideband cancellation or the indication to disable the frequency dependent residual sideband cancellation is included in a single bit of the physical downlink control channel message.

Aspect 29: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-28.

Aspect 30: An apparatus for wireless communication at a device, the apparatus comprising one or more memories and one or more processors coupled to the one or more memories, the one or more processors configured to cause the device to perform the method of one or more of Aspects 1-28.

Aspect 31: An apparatus for wireless communication, the apparatus comprising at least one means for performing the method of one or more of Aspects 1-28.

Aspect 32: A non-transitory computer-readable medium storing code for wireless communication, the code comprising instructions executable by one or more processors to perform the method of one or more of Aspects 1-28.

Aspect 33: A non-transitory computer-readable medium storing a set of instructions for wireless communication, the set of instructions comprising one or more instructions that, when executed by one or more processors of a device, cause the device to perform the method of one or more of Aspects 1-28.

Aspect 34: A device for wireless communication, the device comprising a processing system that includes one or more processors and one or more memories coupled with the one or more processors, the processing system configured to cause the device to perform the method of one or more of Aspects 1-28.

Aspect 35: An apparatus for wireless communication at a device, the apparatus comprising one or more memories and one or more processors coupled to the one or more memories, the one or more processors individually or collectively configured to cause the device to perform the method of one or more of Aspects 1-28.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein. “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus for wireless communication at a network node, comprising:
one or more memories; and
one or more processors coupled to the one or more memories, the one or more processors individually or collectively configured to cause the network node to:
measure a frequency dependent residual sideband distortion;
calculate a thermal noise based at least in part on the frequency dependent residual sideband distortion and a signal-to-noise ratio;
identify, based at least in part on the thermal noise, the frequency dependent residual sideband distortion, and a modulation and coding scheme, whether to enable or disable frequency dependent residual sideband cancellation at a device; and
transmit an indication for the device to enable the frequency dependent residual sideband cancellation or an indication for the device to disable the frequency dependent residual sideband cancellation.

2. The apparatus of claim 1, wherein the one or more processors are further configured to cause the network node to generate, based at least in part on identifying whether to enable or disable the frequency dependent residual sideband cancellation at the device, a frequency dependent residual sideband cancellation message that indicates for the device to enable the frequency dependent residual sideband cancellation or that indicates for the device to disable the frequency dependent residual sideband cancellation,
wherein the one or more processors, to cause the network node to transmit the indication for the device to enable the frequency dependent residual sideband cancellation or the indication for the device to disable the frequency dependent residual sideband cancellation, are configured to cause the network node to transmit, to the device, the frequency dependent residual sideband cancellation message that indicates for the device to enable the frequency dependent residual sideband cancellation or that indicates for the device to disable the frequency dependent residual sideband cancellation.

3. The apparatus of claim 1, wherein the one or more processors, to cause the network node to calculate the thermal noise based at least in part on the frequency dependent residual sideband distortion and the signal-to-noise ratio, are configured to cause the network node to calculate the thermal noise based at least in part on subtracting the frequency dependent residual sideband distortion from a quotient of one divided by the signal-to-noise ratio.

4. The apparatus of claim 1, wherein the frequency dependent residual sideband distortion is based at least in part on a synchronization difference between an in-phase mixer and a quadrature mixer.

5. The apparatus of claim 1, wherein the one or more processors, to cause the network node to measure the frequency dependent residual sideband distortion, are configured to cause the network node to divide a first parameter by a second parameter, the first parameter being based at least in part on subtracting a product of a gain offset and a phase offset from one, and the second parameter being based at least in part on adding one to the product of the gain offset and the phase offset.

6. The apparatus of claim 1, wherein the one or more processors, to cause the network node to calculate the thermal noise, are configured to cause the network node to calculate a total channel noise.

7. The apparatus of claim 1, wherein the one or more processors, to cause the network node to calculate the thermal noise based at least in part on the frequency dependent residual sideband distortion and the signal-to-noise ratio, are configured to cause the network node to calculate the thermal noise based at least in part on the frequency dependent residual sideband distortion, the signal-to-noise ratio, and at least one other noise parameter.

8. The apparatus of claim 1, wherein the one or more processors, to cause the network node to identify whether to enable or disable the frequency dependent residual sideband cancellation, are configured to cause the network node to identify to disable the frequency dependent residual sideband cancellation based at least in part on a frequency dependent residual sideband power level being less than the thermal noise by a threshold amount.

9. The apparatus of claim 1, wherein the one or more processors, to cause the network node to identify whether to enable or disable the frequency dependent residual sideband cancellation, are configured to cause the network node to identify to enable the frequency dependent residual sideband cancellation based at least in part on a frequency dependent residual sideband power level not being less than the thermal noise by a threshold amount.

10. The apparatus of claim 1, wherein the one or more processors, to cause the network node to identify whether to enable or disable the frequency dependent residual sideband cancellation, are configured to cause the network node to identify to disable the frequency dependent residual sideband cancellation based at least in part on the signal-to-noise ratio being sufficient for decoding a signal using the modulation and coding scheme without applying the frequency dependent residual sideband cancellation.

11. The apparatus of claim 1, wherein the one or more processors, to cause the network node to identify whether to enable or disable the frequency dependent residual sideband cancellation, are configured to cause the network node to identify to enable the frequency dependent residual sideband cancellation based at least in part on the signal-to-noise ratio not being sufficient for decoding a signal using the modulation and coding scheme without applying the frequency dependent residual sideband cancellation.

12. The apparatus of claim 1, wherein the one or more processors are further configured to cause the network node to receive an indication of the signal-to-noise ratio from the device.

13. The apparatus of claim 1, wherein the one or more processors, to cause the network node to transmit the indication for the device to enable the frequency dependent residual sideband cancellation or to disable the frequency dependent residual sideband cancellation, are configured to cause the network node to transmit a physical downlink control channel message that includes the indication for the device to enable the frequency dependent residual sideband cancellation or to disable the frequency dependent residual sideband cancellation.

14. The apparatus of claim 13, wherein the indication for the device to enable the frequency dependent residual sideband cancellation or the indication for the device to disable the frequency dependent residual sideband cancellation is included in a single bit of the physical downlink control channel message.

15. An apparatus for wireless communication at a user equipment (UE), comprising:
one or more memories; and
one or more processors coupled to the one or more memories, the one or more processors individually or collectively configured to cause the UE to:
receive an indication to enable frequency dependent residual sideband cancellation or an indication to disable frequency dependent residual sideband cancellation; and
selectively perform frequency dependent residual sideband cancellation in accordance with the indication to enable the frequency dependent residual sideband cancellation or the indication to disable frequency dependent residual sideband cancellation.

16. The apparatus of claim 15, wherein the one or more processors, to cause the UE to receive the indication to enable the frequency dependent residual sideband cancellation or the indication to disable the frequency dependent residual sideband cancellation, are configured to cause the UE to receive a frequency dependent residual sideband cancellation message that indicates for the UE to enable the frequency dependent residual sideband cancellation or that indicates for the UE to disable the frequency dependent residual sideband cancellation.

17. The apparatus of claim 15, wherein the one or more processors, to receive the indication to enable the frequency dependent residual sideband cancellation or the indication to disable the frequency dependent residual sideband cancellation, are configured to cause the UE to receive the indication to enable the frequency dependent residual sideband cancellation, and wherein selectively performing the frequency dependent residual sideband cancellation comprises performing the frequency dependent residual sideband cancellation based at least in part on receiving the indication to enable the frequency dependent residual sideband cancellation.

18. The apparatus of claim 15, wherein the one or more processors, to receive the indication to enable the frequency dependent residual sideband cancellation or the indication to disable the frequency dependent residual sideband cancellation, are configured to cause the UE to receive the indication to disable the frequency dependent residual sideband cancellation, and wherein selectively performing the frequency dependent residual sideband cancellation comprises refraining from performing the frequency dependent residual sideband cancellation based at least in part on receiving the indication to disable the frequency dependent residual sideband cancellation.

19. The apparatus of claim 15, wherein the indication to enable the frequency dependent residual sideband cancellation or the indication to disable the frequency dependent residual sideband cancellation is based at least on part on a thermal noise measurement, a frequency dependent residual sideband distortion measurement, and a modulation and coding scheme.

20. The apparatus of claim 15, wherein the one or more processors are further configured to cause the UE to transmit an indication of a signal-to-noise ratio, wherein the indication to enable the frequency dependent residual sideband cancellation or the indication to disable the frequency dependent residual sideband cancellation is based at least on part on the signal-to-noise ratio.

21. The apparatus of claim 15, wherein the one or more processors, to cause the UE to selectively perform the frequency dependent residual sideband cancellation, are configured to cause the UE to selectively perform the frequency dependent residual sideband cancellation during a signal demodulation process performed by the UE.

22. The apparatus of claim 15, wherein a frequency dependent residual sideband distortion associated with the frequency dependent residual sideband cancellation is based at least in part on a synchronization difference between an in-phase mixer and a quadrature mixer.

23. The apparatus of claim 15, wherein the one or more processors, to cause the UE to receive the indication to enable the frequency dependent residual sideband cancellation or the indication to disable the frequency dependent residual sideband cancellation, are configured to cause the UE to receive an indication to disable the frequency dependent residual sideband cancellation based at least in part on a frequency dependent residual sideband power level being less than a thermal noise by a threshold amount.

24. The apparatus of claim 15, wherein the one or more processors, to cause the UE to receive the indication to enable the frequency dependent residual sideband cancellation or to disable the frequency dependent residual sideband cancellation, are configured to cause the UE to receive an indication to enable the frequency dependent residual sideband cancellation based at least in part on a frequency dependent residual sideband power level not being less than a thermal noise by a threshold amount.

25. The apparatus of claim 15, wherein the one or more processors, to cause the UE to receive the indication to enable the frequency dependent residual sideband cancellation or the indication to disable the frequency dependent residual sideband cancellation, are configured to cause the UE to receive an indication to disable the frequency dependent residual sideband cancellation based at least in part on a signal-to-noise ratio being sufficient for decoding a signal using a modulation and coding scheme without applying the frequency dependent residual sideband cancellation.

26. The apparatus of claim 15, wherein the one or more processors, to cause the UE to receive the indication to enable the frequency dependent residual sideband cancellation or the indication to disable the frequency dependent residual sideband cancellation, are configured to cause the UE to receive an indication to enable the frequency dependent residual sideband cancellation based at least in part on a signal-to-noise ratio not being sufficient for decoding a signal using a modulation and coding scheme without applying the frequency dependent residual sideband cancellation.

27. The apparatus of claim 15, wherein the one or more processors, to cause the UE to receive the indication to enable the frequency dependent residual sideband cancellation or the indication to disable the frequency dependent residual sideband cancellation, are configured to cause the UE to receive a physical downlink control channel message that includes the indication to enable the frequency dependent residual sideband cancellation or that indicates to disable the frequency dependent residual sideband cancellation.

28. The apparatus of claim 27, wherein the indication to enable the frequency dependent residual sideband cancellation or the indication to disable the frequency dependent residual sideband cancellation is included in a single bit of the physical downlink control channel message.

29. A method of wireless communication performed by a network node, comprising:
measuring a frequency dependent residual sideband distortion;
calculating a thermal noise based at least in part on the frequency dependent residual sideband distortion and a signal-to-noise ratio;
identifying, based at least in part on the thermal noise, the frequency dependent residual sideband distortion, and a modulation and coding scheme, whether to enable or disable frequency dependent residual sideband cancellation at a device; and
transmitting an indication for the device to enable the frequency dependent residual sideband cancellation or an indication for the device to disable the frequency dependent residual sideband cancellation.

30. A method of wireless communication performed by a user equipment (UE), comprising:
receiving an indication to enable frequency dependent residual sideband cancellation or an indication to disable frequency dependent residual sideband cancellation; and
selectively performing frequency dependent residual sideband cancellation in accordance with the indication to enable the frequency dependent residual sideband cancellation or the indication to disable frequency dependent residual sideband cancellation.
